(19) United States
(12) Patent Application Publication
(10) Pub. No.: US 2026/0019043 A1
(43) Pub. Date: Jan. 15, 2026

(54) POWER AMPLIFIER CIRCUIT AND POWER AMPLIFICATION METHOD

(71) Applicant: Murata Manufacturing Co., Ltd., Nagaokakyo-shi (JP)

(72) Inventor: Kiichiro Takenaka, Nagaokakyo-shi (JP)

(21) Appl. No.: 19/332,442

(22) Filed: Sep. 18, 2025

Related U.S. Application Data
(63) Continuation of application No. PCT/JP2024/004769, filed on Feb. 13, 2024.

(30) Foreign Application Priority Data
Mar. 31, 2023 (JP) 2023-057511

(51) Int. Cl. H03F 1/02; H03F 1/32; H03F 3/24

(52) U.S. Cl. CPC H03F 1/0288; H03F 1/3241; H03F 3/245; H03F 2200/451

(57) ABSTRACT

A power amplifier circuit includes a first power amplifier that amplifies a radio frequency signal using multiple discrete voltages; a second power amplifier that amplifies the radio frequency signal; a bias circuit that supplied a first bias voltage to the first power amplifier when a first power supply voltage is supplied to the first power amplifier and a second bias voltage lower than the first bias voltage to the first power amplifier when a second power supply voltage higher than the first power supply voltage is supplied to the first power amplifier; and a bias circuit that supplied a third bias voltage to the second power amplifier when the first power supply voltage is supplied to the second power amplifier and a fourth bias voltage higher than the third bias voltage to the second power amplifier when the second power supply voltage is supplied to the power amplifier.

### CROSS REFERENCE TO RELATED APPLICATIONS

This application is a continuation of International Application No. PCT/JP2024/004769, filed Feb. 13, 2024, which claims priority to Japanese Patent Application No. Application No. 2023-057511, filed Mar. 31, 2023, the contents of each of which are hereby incorporated by reference in their entireties.

### TECHNICAL FIELD

The present disclosure relates to a power amplifier circuit and a power amplification method.

### BACKGROUND

In recent years, power-added efficiency has been improved by applying tracking technologies to power amplifier circuits. U.S. Pat. No. 8,829,993 discloses a tracker circuit for digital envelope tracking (D-ET) in which a power amplifier circuit is supplied with a power supply voltage whose level changes discretely over time based on an envelope signal (hereinafter simply referred to as “multiple discrete voltages”). Moreover, U.S. Patent No. 10, 686, 407 discloses a tracker circuit for symbol power tracking (SPT) in which a power amplifier circuit is supplied with multiple discrete voltages based on symbols.

In the technologies described in the above-noted patent documents, digital pre-distortion (DPD) is sometimes used to reduce nonlinear distortion caused by a power amplifier circuit operating in a nonlinear region. In DPD, the input signal of the power amplifier circuit is distorted in advance in order to cancel out the nonlinear distortion caused by the power amplifier circuit.

However, when multiple discrete voltages are supplied to the power amplifier circuit, the reduction of nonlinear distortion achieved by DPD may be limited.

### SUMMARY OF THE INVENTION

Accordingly, the exemplary aspects of the present disclosure provide a power amplifier circuit and a power amplification method that reduces nonlinear distortion.

According to an exemplary aspect, a power amplifier circuit is provided that includes a first power amplifier configured to amplify a radio frequency signal using multiple discrete voltages that includes a first power supply voltage and a second power supply voltage higher than the first power supply voltage; a second power amplifier configured to amplify the radio frequency signal amplified by the first power amplifier using multiple discrete voltages; a first bias circuit configured to supply a first bias voltage to the first power amplifier when the first power supply voltage is supplied to the first power amplifier, and to supply a second bias voltage lower than the first bias voltage to the first power amplifier when the second power supply voltage is supplied to the first power amplifier; and a second bias circuit configured to supply a third bias voltage to the second power amplifier when the first power supply voltage is supplied to the second power amplifier, and to supply a fourth bias voltage higher than the third bias voltage to the second power amplifier when the second power supply voltage is supplied to the second power amplifier.

According to another exemplary aspect, a power amplifier circuit is provided that includes a first power amplifier configured to amplify a radio frequency signal using multiple discrete voltages including a first power supply voltage and a second power supply voltage higher than the first power supply voltage; a second power amplifier configured to amplify the radio frequency signal amplified by the first power amplifier using multiple discrete voltages; a first bias circuit configured to supply a bias voltage to the first power amplifier; a second bias circuit configured to supply a first bias voltage to the second power amplifier when the first power supply voltage is supplied to the second power amplifier and to supply a second bias voltage higher than the first bias voltage to the second power amplifier when the second power supply voltage is supplied to the second power amplifier; and a variable attenuation circuit connected to an input terminal of the first power amplifier or connected between an output terminal of the first power amplifier and an input terminal of the second power amplifier. The variable attenuation circuit is adjusted to a first attenuation when the first power supply voltage is supplied to the first power amplifier and is adjusted to a second attenuation greater than the first attenuation when the second power supply voltage is supplied to the first power amplifier.

Moreover, in another exemplary aspect, a power amplification method for amplifying a radio frequency signal using multiple discrete voltages is provided that includes receiving a first power supply voltage included in the multiple discrete voltages; supplying a first bias voltage to a first power amplifier based on the first power supply voltage; amplifying a first radio frequency signal in the first power amplifier using the first power supply voltage and the first bias voltage; supplying a third bias voltage to a second power amplifier based on the first power supply voltage; amplifying the first radio frequency signal amplified in the first power amplifier in the second power amplifier using the first power supply voltage and the third bias voltage; receiving a second power supply voltage that is included in the multiple discrete voltages and is higher than the first power supply voltage; supplying a second bias voltage, which is lower than the first bias voltage, to the first power amplifier based on the second power supply voltage; amplifying a second radio frequency signal in the first power amplifier using the second power supply voltage and the second bias voltage; supplying a fourth bias voltage, which is higher than the third bias voltage, to the second power amplifier based on the second power supply voltage; and amplifying the second radio frequency signal amplified in the first power amplifier in the second power amplifier using the second power supply voltage and the fourth bias voltage.

According to the exemplary aspects of the present disclosure, nonlinear distortion is reduced.

### BRIEF DESCRIPTION OF DRAWINGS

FIG. 1A is a graph illustrating an example of the transitions of a power supply voltage in an average power tracking (APT) mode.

FIG. 1B is a graph illustrating an example of the transitions of a power supply voltage in an analog envelope tracking (A-ET) mode.

FIG. 1C is a graph illustrating an example of the transitions a power supply voltage in a D-ET mode.

FIG. 2 is a circuit configuration diagram of a communication device according to Exemplary Embodiment 1 and Modification 1 thereof.

FIG. 3A is a circuit configuration diagram of a first bias circuit according to Exemplary Embodiment 1.

FIG. 3B is a diagram illustrating the relationship between the bias voltage supplied from the first bias circuit according to Exemplary Embodiment 1 and the power supply voltage.

FIG. 4A is a circuit configuration diagram of a second bias circuit according to Exemplary Embodiment 1.

FIG. 4B is a diagram illustrating the relationship between the bias voltage supplied from the second bias circuit according to Exemplary Embodiment 1 and the power supply voltage.

FIG. 5 is a layout diagram of a power amplifier circuit according to Exemplary Embodiment 1.

FIG. 6 is a flowchart of a power amplification method according to Exemplary Embodiment 1.

FIG. 7A is a diagram illustrating the gain characteristics with respect to the output power of the power amplifier circuit according to Exemplary Embodiment 1.

FIG. 7B is a diagram illustrating the gain characteristics with respect to the output power of a power amplifier circuit of the related art.

FIG. 8 is a diagram illustrating operating points of second power amplifiers of Embodiment 1 and the related art.

FIG. 9A is a diagram illustrating gain characteristics with respect to output power of the second power amplifier of the related art.

FIG. 9B is a diagram illustrating gain characteristics with respect to output power of the second power amplifier according to Exemplary Embodiment 1.

FIG. 10A is a diagram illustrating gain characteristics with respect to output power of a first power amplifier of the related art.

FIG. 10B is a diagram illustrating gain characteristics with respect to output power of a first power amplifier according to Exemplary Embodiment 1.

FIG. 11 is a circuit configuration diagram of a first bias circuit according to Modification 1 of Exemplary Embodiment 1.

FIG. 12A is a diagram illustrating the relationship between the bias voltage supplied from the first bias circuit according to Modification 1 of Exemplary Embodiment 1 and the power supply voltage.

FIG. 12B is a diagram illustrating the relationship between the bias voltage supplied from the first bias circuit according to Modification 1 of Exemplary Embodiment 1 and the power supply voltage.

FIG. 13 is a circuit configuration diagram of a communication device according to Modification 2 of Exemplary Embodiment 1.

FIG. 14A is a circuit configuration diagram of a third bias circuit according to Modification 2 of Exemplary Embodiment 1.

FIG. 14B is a diagram illustrating the relationship between the bias voltage supplied from the third bias circuit according to Modification 2 of Exemplary Embodiment 1 and the power supply voltage.

FIG. 15 is a circuit configuration diagram of a communication device according to Exemplary Embodiment 2.

FIG. 16A is a diagram illustrating the relationship between the bias voltage supplied from a first bias circuit according to Exemplary Embodiment 2 and the power supply voltage.

FIG. 16B is a diagram illustrating the relationship between the attenuation of a variable attenuation circuit according to Exemplary Embodiment 2 and the power supply voltage.

FIG. 17 is a layout diagram of a power amplifier circuit according to Exemplary Embodiment 2.

### DETAILED DESCRIPTION OF EMBODIMENTS

Hereafter, exemplary embodiments will be described in detail with reference to the drawings. The embodiments described hereafter each illustrate a comprehensive or specific example of the present disclosure. The numerical values, shapes, materials, components, the arrangement of the components and the way in which the components are connected, steps, and the order of steps illustrated in the following embodiments are merely examples and are not intended to limit the exemplary aspects of the present disclosure.

It is noted that the drawings are schematic diagrams in which certain elements are emphasized or omitted or their proportions are adjusted as appropriate, the drawings are not necessarily illustrated in a strictly accurate manner, and the actual shapes, positional relationships, and proportions may be different. In the drawings, configurations that are substantially the same as each other may be denoted by the same symbols and repeated description thereof may be omitted or simplified.

In the drawings referred to below and for purposes of the present disclosure, an x axis and a y axis are mutually perpendicular axes on a plane that is parallel to main surfaces of a module substrate. Specifically, when the module substrate has a rectangular shape in plan view, the x-axis is parallel to a first edge of the module substrate and the y-axis is parallel to a second edge of the module substrate that is perpendicular to the first edge. In addition, a z axis is an axis that is perpendicular to the main surfaces of the module substrate, and a positive z axis direction indicates an upward direction and a negative z axis direction indicates a downward direction.

In the following description of circuit configurations, the term “connected” includes not only the case where the components are directly connected by connection terminals and/or wiring conductors, but also the case where the components are electrically connected via other circuit elements. The phrase “directly connected” can indicate directly connected by a connection terminal and/or a wiring conductor without the interposition of other circuit elements. The phrase “C is connected between A and B” indicates that one end of C is connected to A and the other end of C is connected to B, and indicates that C is disposed in series on a path connecting A and B. The phrase “path connecting A and B” indicates a path comprising a conductor that electrically connects A to B.

In the following descriptions of circuit configurations, the term “terminal” refers to a point where a conductor in an element ends. Note that, when the impedance of the conductor between elements is sufficiently low, a terminal is interpreted not only as a single point, but also as any point on the conductor between elements or the entire conductor.

In the following descriptions of circuit layouts, the expression “C is disposed closer to A than B” can indicate that the distance between A and C is shorter than the distance between A and B. Here, the expression “the distance between A and B” indicates the shortest distance between A and B. In other words, “the distance between A and B” indicates the length of the shortest line segment among multiple line segments connecting any point on the surface of A and any point on the surface of B.

In addition, terms indicating the relationships between elements, such as “parallel” and “perpendicular”, terms indicating the shape of elements such as “rectangular”, and numerical ranges do not express only a strict meaning, but rather are intended to include substantially equivalent ranges, for example, differences of several percent as would be appreciated to one skilled in the art.

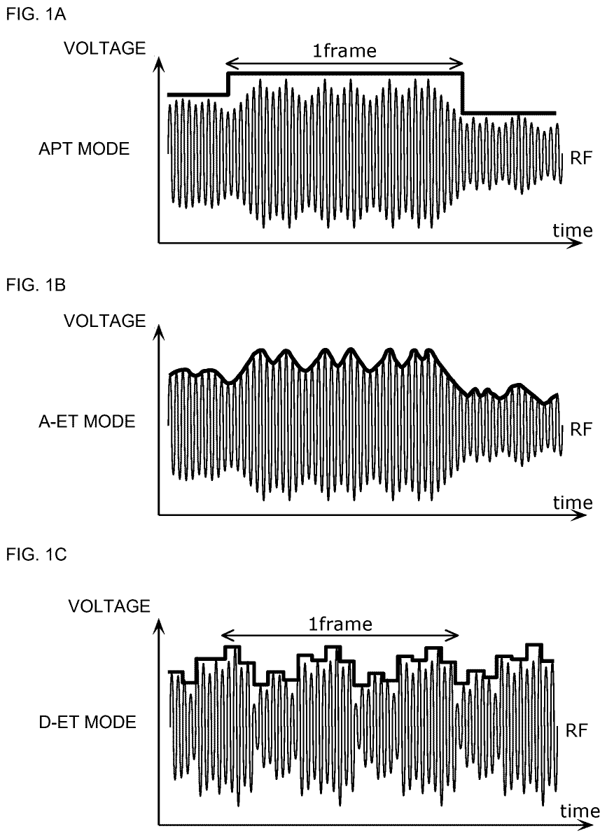

First, as a technology for amplifying radio frequency signals with high efficiency, a tracking mode will be described in which a power amplifier is supplied with a power supply voltage that is dynamically adjusted over time based on the radio frequency signal. A “tracking mode” is a mode in which a power supply voltage applied to a power amplifier is dynamically adjusted. There are several types of tracking mode, but here, an APT mode, an A-ET mode, and a D-ET mode are described with reference to FIGS. 1A to 1C. In FIGS. 1A to 1C, the horizontal axis represents time and the vertical axis represents voltage. In addition, the thick solid line represents the power supply voltage, and the thin solid line (e.g., waveform) represents the modulated signal.

FIG. 1A is a graph illustrating an example of the transitions of the power supply voltage in the APT mode. The APT mode is a mode in which the power supply voltage is varied to multiple discrete voltage levels in units of one frame based on the average power.

According to an exemplary aspect, a frame refers to a unit forming a radio frequency signal (e.g., a modulated signal). For example, in fifth Generation New Radio (5GNR) and Long Term Evolution (LTE), a frame includes 10 subframes, each subframe includes multiple slots, and each slot includes multiple symbols. The subframe length is 1 ms, and the frame length is 10 ms according to the exemplary aspect.

It is noted that a mode in which the voltage level is changed in units of one frame or units larger than one frame based on the average power is called an APT mode, and is distinguished from a mode in which the voltage level is changed in units smaller than one frame (for example, units of subframe, slot, or symbol).

FIG. 1B is a graph illustrating an example of the transitions of the power supply voltage in the A-ET mode. The A-ET mode is a mode in which the power supply voltage is changed continuously based on an envelope signal. In the A-ET mode, the envelope of the modulated signal is tracked.

The envelope signal is a signal that indicates the envelope of the modulated signal. The envelope value is expressed, for example, as the square root of (I²+Q²). Here, (I, Q) represent a constellation point. A constellation point is a point that represents a digitally modulated signal on a constellation diagram. (I, Q) are determined, for example, by a baseband integrated circuit (BBIC) based on transmission information.

FIG. 1C is a graph illustrating an example of the transitions of the power supply voltage in the D-ET mode. The D-ET mode is a mode in which the power supply voltage is changed to multiple discrete voltage levels within a single frame based on an envelope signal. In the D-ET mode, the envelope of the modulated signal is tracked.

### Exemplary Embodiment 1

Embodiment 1 is described hereafter.

### 1.1 Circuit Configuration of Communication Device 6

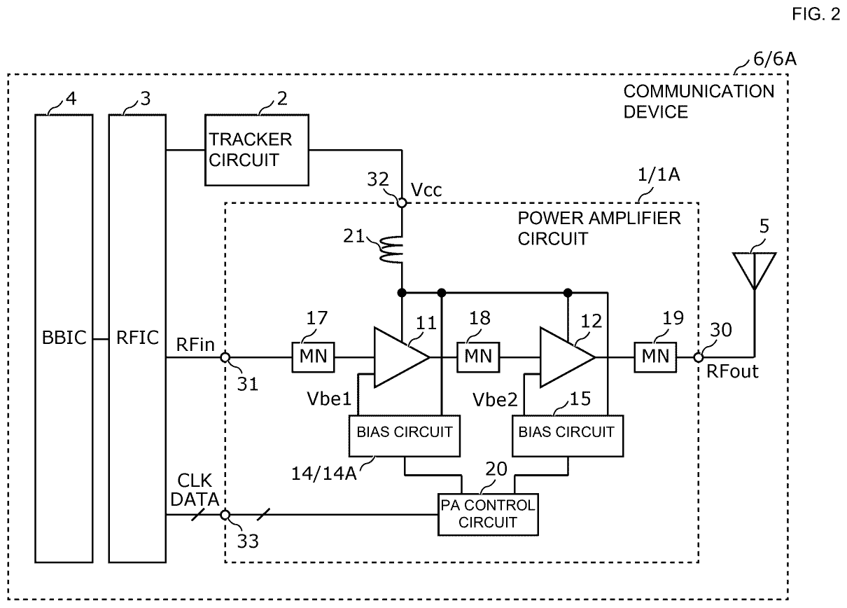

First, the circuit configuration of a communication device 6 according to this embodiment will be described with reference to FIG. 2. FIG. 2 is a circuit configuration diagram of the communication device 6 according to this exemplary embodiment.

It is also noted that FIG. 2 depicts an exemplary circuit configuration, and the communication device 6 may be implemented using any of a wide variety of circuit implementations and circuit technologies. Therefore, the description of the communication device 6 provided below is not to be interpreted as limiting.

The communication device 6 according to this embodiment is implemented as a user terminal (user equipment (UE)) in a cellular network, and is typically a mobile phone, a smartphone, a tablet computer, a wearable device, or the like. Note that the communication device 6 may also be implemented as an Internet of Things (IoT) sensor device, a medical/healthcare device, a car, an unmanned aerial vehicle (UAV) (so-called drone), or an automated guided vehicle (AGV). The communication device 6 may also be implemented as a base station (BS) in a cellular network or an access point in a wireless local area network (WLAN).

As illustrated in FIG. 2, the communication device 6 includes a power amplifier circuit 1, a tracker circuit 2, a radio frequency integrated circuit (RFIC) 3, a BBIC 4, and an antenna 5.

The power amplifier circuit 1 is a multi-stage amplifier circuit and can amplify a radio frequency signal supplied from the RFIC 3. The circuit configuration of the power amplifier circuit 1 will be described later.

The tracker circuit 2 can be configured to supply multiple discrete voltages to the power amplifier circuit 1 as a power supply voltage (Vcc) based on a tracking mode applied to the power amplifier circuit 1. In this embodiment, the D-ET mode or SPT mode and the APT mode can be switched between and used as the tracking mode, but the tracking modes that can be used are not limited to these modes.

It is noted that, as the tracker circuit 2, an existing tracker circuit 2 that operates in the D-ET mode or SPT mode and APT mode can be used, and for example, the tracker circuit described in U.S. Pat. No. 8,829,993 and/or U.S. Pat. No. 10,686,407 can be used. Thus, it is noted that the tracker circuit 2 is not limited to these tracker circuits as would be appreciated to one skilled in the art.

The RFIC 3 is an example of a signal processing circuit that is configured to process radio frequency signals. The RFIC 3 can receive digital IQ signals from the BBIC 4 and supply a radio frequency signal to the power amplifier circuit 1.

Specifically, the RFIC 3 can pre-distort the digital IQ signals supplied from the BBIC 4 based on a DPD mathematical model. As the mathematical model, for example, a memoryless polynomial model, a memory polynomial model (MPM), a generalized memory polynomial model (GMP), or the like can be used, but the mathematical model is not limited to these mathematical models.

Then, the RFIC 3 can convert the pre-distorted digital IQ signals into pre-distorted analog IQ signals. The RFIC 3 can generate a radio frequency signal by performing quadrature modulation and up-conversion on the analog IQ signals. The generated radio frequency signal is supplied to a radio-frequency input terminal 31 of the power amplifier circuit 1.

Furthermore, the RFIC 3 includes a control unit that controls bias circuits 14 and 15 and so forth of the power amplifier circuit 1. The control unit of the RFIC 3 can supply digital control signals to a control terminal 33 of the power amplifier circuit 1. It is noted that some or all of the functions of the control unit of the RFIC 3 may be implemented outside the RFIC 3, for example, in the BBIC 4, the power amplifier circuit 1, or the tracker circuit 2 as would be appreciated to one skilled in the art.

The BBIC 4 is a baseband signal processing circuit that is configured to perform signal processing using a frequency band lower than that of the radio frequency signals. The BBIC 4 digitally modulates, for example, an image signal for image display and/or a bit sequence representing an audio signal for communication via a speaker and generates digital IQ signals. The generated digital IQ signals are supplied to the RFIC 3. It is noted that the BBIC 4 may be omitted from the communication device 6 in an exemplary aspect.

The antenna 5 is connected to an antenna connection terminal 30 of the power amplifier circuit 1, and can output the radio frequency signal amplified by the power amplifier circuit 1 to the space outside the communication device 6. The antenna 5 may be omitted from the communication device 6 in an exemplary aspect. Moreover, the communication device 6 may further include one or more antennas in addition to the antenna 5.

### 1.2 Circuit Configuration of Power Amplifier Circuit 1

Next, the circuit configuration of the power amplifier circuit 1 according to this embodiment will be described with reference to FIG. 2. The power amplifier circuit 1 includes power amplifiers 11 and 12, bias circuits 14 and 15, matching circuits (e.g., matching networks) 17 to 19, a PA control circuit 20, and an inductor 21.

The power amplifier 11 is an example of a “first power amplifier” according to the exemplary aspect, and is connected between the radio-frequency input terminal 31 and the power amplifier 12. Specifically, an input terminal of the power amplifier 11 is connected to the radio-frequency input terminal 31 via the matching circuit 17, and an output terminal of the power amplifier 11 is connected to the input terminal of the power amplifier 12 via the matching circuit 18. Furthermore, the power amplifier 11 is connected to the bias circuit 14, and is connected to a power supply voltage terminal 32 via the inductor 21. As a result, the power amplifier 11 can amplify a radio frequency signal (RFin) supplied from the RFIC 3 using a bias voltage (Vbe1) supplied from the bias circuit 14 and the power supply voltage (Vcc) supplied from the tracker circuit 2.

The power amplifier 12 is an example of a “second power amplifier” according to the exemplary aspect, and is connected between the power amplifier 11 and the antenna connection terminal 30. Specifically, the input terminal of the power amplifier 12 is connected to the output terminal of the power amplifier 11 via the matching circuit 18, and the output terminal of the power amplifier 12 is connected to the antenna connection terminal 30 via the matching circuit 19. Furthermore, the power amplifier 12 is connected to the bias circuit 15, and is connected to the power supply voltage terminal 32 via the inductor 21. As a result, the power amplifier 12 can amplify the radio frequency signal amplified by the power amplifier 11 using a bias voltage (Vbe2) supplied from the bias circuit 15 and the power supply voltage (Vcc) supplied from the tracker circuit 2.

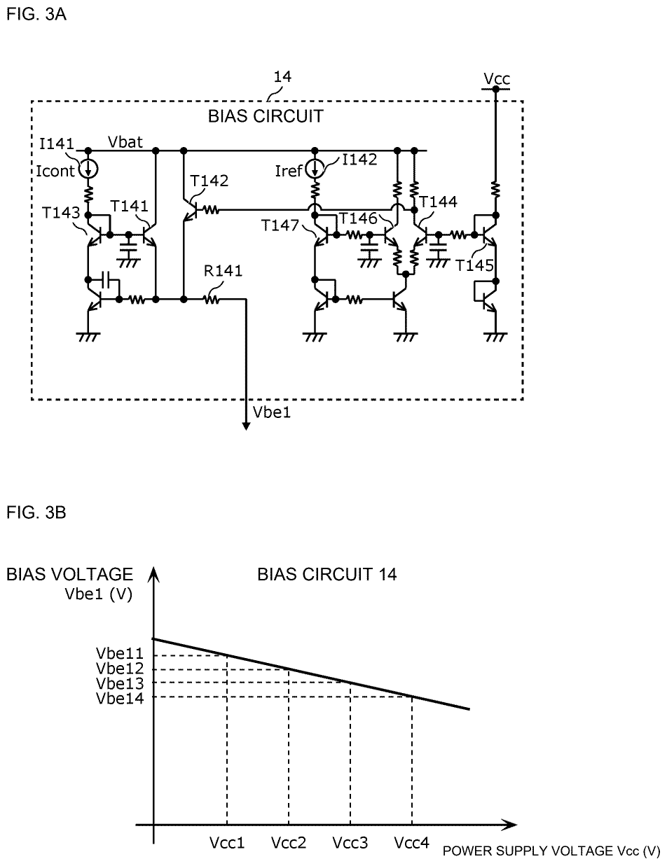

The bias circuit 14 is an example of a “first bias circuit” according to the exemplary aspect, and is connected to the power amplifier 11. The bias circuit 14 can supply the bias voltage (Vbe1) to the power amplifier 11. The bias circuit 14 can change the bias voltage (Vbe1) in accordance with the power supply voltage (Vcc) supplied to the power amplifier 11. Details of the bias circuit 14 and the bias voltage (Vbe1) will be described later using FIG. 3A and FIG. 3B.

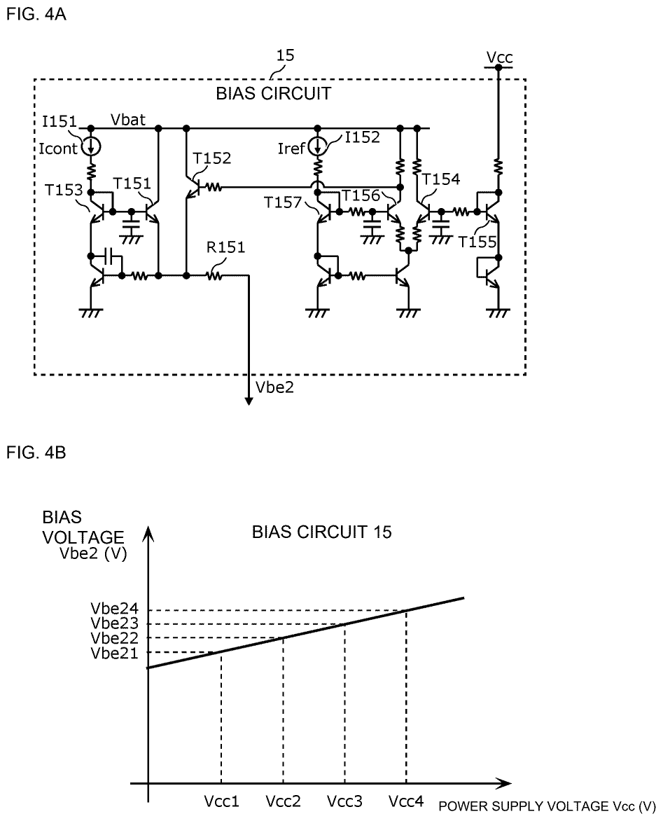

The bias circuit 15 is an example of a “second bias circuit” according to the exemplary aspect, and is connected to the power amplifier 12. The bias circuit 15 can supply a bias voltage (Vbe2) to the power amplifier 12. The bias circuit 15 can change the bias voltage (Vbe2) in accordance with the power supply voltage (Vcc) supplied to the power amplifier 12. Details of the bias circuit 15 and the bias voltage (Vbe2) will be described later using FIG. 4A and FIG. 4B.

The matching circuit 17 is connected between the radio-frequency input terminal 31 and the power amplifier 11. Alternatively, the matching circuit 17 may be connected between the path between the radio-frequency input terminal 31 and the power amplifier 11, and the ground. The matching circuit 17 is an impedance matching circuit and can achieve impedance matching between the radio-frequency input terminal 31 and the input terminal of the power amplifier 11. The matching circuit 17 may comprise, for example, an inductor and/or a capacitor, or may comprise of a transformer. It is noted that the matching circuit 17 may be omitted from the power amplifier circuit 1 in an exemplary aspect.

The matching circuit 18 is connected between the power amplifiers 11 and 12. Alternatively, the matching circuit 18 may be connected between the path between the power amplifiers 11 and 12, and the ground. The matching circuit 18 is an impedance matching circuit and can achieve impedance matching between the output terminal of the power amplifier 11 and the input terminal of the power amplifier 12. The matching circuit 18 may comprise, for example, an inductor and/or a capacitor, or may comprise a transformer. The matching circuit 18 may be omitted from the power amplifier circuit 1 in an exemplary aspect.

The matching circuit 19 is connected between the power amplifier 12 and the antenna connection terminal 30. Alternatively, the matching circuit 19 may be connected between the path between the power amplifier 12 and the antenna connection terminal 30, and the ground. The matching circuit 19 is an impedance matching circuit, and can achieve impedance matching between the output terminal of the power amplifier 12 and the antenna connection terminal 30. The matching circuit 19 may comprise, for example, an inductor and/or a capacitor, or may comprise a transformer. The matching circuit 19 may be omitted from the power amplifier circuit 1 in an exemplary aspect.

The PA control circuit 20 is connected to the control terminal 33, and can receive digital control signals from the RFIC 3 via the control terminal 33. The PA control circuit 20 can control the bias circuits 14 and 15 based on the digital control signal. For example, the PA control circuit 20 can control the bias circuits 14 and 15 in units of a frame of a radio frequency signal. The PA control circuit 20 may be omitted from the power amplifier circuit 1 in an exemplary aspect.

As the digital control signals, for example, serial data signals are used. More specifically, as the digital control signals, source synchronous serial data signals (a clock signal (CLK) and a data signal (DATA)) are used. The digital control signals are not limited to source synchronous serial data signals. For example, serial data signals using an embedded clock scheme may be used as the digital control signals.

The inductor 21 is a so-called choke inductor, and is connected between the power supply voltage terminal 32 and the power amplifiers 11 and 12. The inductor 21 may be omitted from the power amplifier circuit 1 in an exemplary aspect.

### 1.2.1 Circuit Configuration of Bias Circuit 14

Next, the circuit configuration of the bias circuit 14 according to this embodiment will be described with reference to FIG. 3A. FIG. 3A is a circuit configuration diagram of the bias circuit 14 according to this embodiment.

It is noted that FIG. 3A depicts an exemplary circuit configuration, and the bias circuit 14 can be implemented using any of a wide variety of circuit implementations and circuit technologies. Therefore, the description of the bias circuit 14 provided below should not be interpreted as limiting.

The bias circuit 14 includes transistors T141 to T147, a resistor R141, a constant current source I141, and a reference current source I142. The constant current source I141 and the reference current source I142 can respectively output a constant current (Icont) and a reference current (Iref) in accordance with a control signal from the PA control circuit 20. In this embodiment, the constant current source I141 and the reference current source I142 can be controlled in units of a frame of a radio frequency signal or units larger than a frame of a radio frequency signal. In other words, the constant current (Icont) and the reference current (Iref) cannot be controlled in units smaller than a frame (for example, units of an envelope or symbol).

In the bias circuit 14, the emitter terminals of the transistors T141 and T142 are connected, via the resistor R141, to an output terminal that supplies the bias voltage (Vbe1) to the power amplifier 11. Therefore, when the sum of the emitter currents of the transistors T141 and T142 increases, the bias voltage (Vbe1) decreases.

The emitter current (collector current) of the transistor T141 depends on the collector current of the transistor T143 connected to the constant current source I141. The collector current of the transistor T143 depends on the constant current (Icont) output from the constant current source I141 and is constant. Therefore, the emitter current of the transistor T141 is constant regardless of the power supply voltage (Vcc) of the power amplifier 11.

The emitter current of the transistor T142 depends on the collector current of the transistor T144 and increases as the collector current of the transistor T144 increases. The collector current of the transistor T144 depends on the collector currents of the transistors T145 and T146 and increases as the collector current of the transistor T145 increases and decreases as the collector current of the transistor T146 increases. The collector current of the transistor T145 depends on the power supply voltage (Vcc) of the power amplifier 11, and increases as the power supply voltage (Vcc) increases. The collector current of the transistor T146 depends on the collector current of the transistor T147, and increases as the collector current of the transistor T147 increases. The collector current of the transistor T147 depends on the reference current (Iref) output from the reference current source I142, and increases as the reference current (Iref) increases. In summary, the emitter current of the transistor T142 increases as the power supply voltage (Vcc) increases, and decreases as the reference current (Iref) increases.

From the above description, when the reference current (Iref) is constant, the sum of the emitter currents of the transistors T141 and T142 increases as the power supply voltage (Vcc) increases. Therefore, in the bias circuit 14, the bias voltage (Vbe1) supplied to the power amplifier 11 decreases as the power supply voltage (Vcc) increases.

The relationship between the bias voltage (Vbe1) and the power supply voltage (Vcc) will be described with reference to FIG. 3B. FIG. 3B is a diagram illustrating the relationship between the bias voltage (Vbe1) supplied from the bias circuit 14 according to this embodiment and the power supply voltage (Vcc). In FIG. 3B, the vertical axis represents the bias voltage (Vbe1), and the horizontal axis represents the power supply voltage (Vcc).

The bias circuit 14 can supply a bias voltage (Vbe11) (an example of a first bias voltage) to the power amplifier 11 when a power supply voltage (Vcc1) (an example of a first power supply voltage) is supplied to the power amplifier 11. Furthermore, the bias circuit 14 can supply a bias voltage (Vbe12) (an example of a second bias voltage) that is lower than the bias voltage (Vbe11) to the power amplifier 11 when a power supply voltage (Vcc2) (an example of a second power supply voltage) that is higher than the power supply voltage (Vcc1) is supplied to the power amplifier 11.

Similarly, when a power supply voltage (Vcc3) that is higher than the power supply voltage (Vcc2) is supplied to the power amplifier 11, the bias circuit 14 can supply a bias voltage (Vbe13) that is lower than the bias voltage (Vbe12) to the power amplifier 11. Furthermore, when a power supply voltage (Vcc4) that is higher than the power supply voltage (Vcc3) is supplied to the power amplifier 11, the bias circuit 14 can supply a bias voltage (Vbe14) that is lower than the bias voltage (Vbe13) to the power amplifier 11.

As described above, the bias circuit 14 can supply a lower bias voltage (Vbe1) to the power amplifier 11 as the power supply voltage (Vcc) supplied to the power amplifier 11 increases. In other words, the bias circuit 14 can supply a bias voltage (Vbe1) having a negative proportional relationship to the power supply voltage (Vcc) to the power amplifier 11. Such a negative proportional relationship can be identified by measuring the bias voltage (Vbe1) at least at three different levels of power supply voltage (Vcc).

It is noted that in this embodiment, the bias voltage (Vbe1) is proportional to the power supply voltage (Vcc), but the relationship between the bias voltage (Vbe1) and the power supply voltage (Vcc) is not limited to being proportional. For example, the bias voltage (Vbe1) may decrease in a stepwise or exponential manner as the power supply voltage (Vcc) increases. Furthermore, in a range of the power supply voltage (Vcc) that is not supplied to the power amplifier 11, the bias voltage (Vbe1) may increase as the power supply voltage (Vcc) increases.

### 1.2.2 Circuit Configuration of Bias Circuit 15

Next, the circuit configuration of the bias circuit 15 according to this embodiment will be described with reference to FIG. 4A. FIG. 4A is a circuit configuration diagram of the bias circuit 15 according to this embodiment.

It is noted that FIG. 4A depicts an exemplary circuit configuration, and the bias circuit 15 may be implemented using any of a wide variety of circuit implementations and circuit technologies. Therefore, the description of the bias circuit 15 provided below should not be interpreted as limiting.

The bias circuit 15 includes transistors T151 to T157, a resistor R151, a constant current source 1151, and a reference current source I152. The constant current source I151 and the reference current source 1152 can respectively output a constant current (Icont) and a reference current (Iref) in accordance with a control signal from the PA control circuit 20. In this embodiment, the constant current source I151 and the reference current source I152 can be controlled in units of a frame of a radio frequency signal or in units larger than a frame of a radio frequency signal. In other words, the constant current (Icont) and the reference current (Iref) cannot be controlled in units smaller than a frame (for example, units of an envelope or symbol).

In the bias circuit 15, the emitter terminals of the transistors T151 and T152 are connected, via the resistor R151, to an output terminal that supplies the bias voltage (Vbe2) to the power amplifier 12. Therefore, when the sum of the emitter currents of the transistors T151 and T152 increases, the bias voltage (Vbe2) decreases.

The emitter current (collector current) of the transistor T151 depends on the collector current of the transistor T153 connected to the constant current source I151. The collector current of the transistor T153 depends on the constant current (Icont) output from the constant current source 1151 and is constant. Therefore, the emitter current of the transistor T151 is constant regardless of the power supply voltage (Vcc) of the power amplifier 12.

The emitter current of the transistor T152 depends on the collector current of the transistor T156 and increases as the collector current of the transistor T156 increases. The collector current of the transistor T156 depends on the collector currents of the transistors T157 and T154 and increases as the collector current of the transistor T157 increases and decreases as the collector current of the transistor T154 increases. The collector current of the transistor T157 depends on the reference current (Iref) output from the reference current source I152, and increases as the reference current (Iref) increases. The collector current of the transistor T154 depends on the collector current of the transistor T155, and increases as the collector current of the transistor T155 increases. The collector current of the transistor T155 depends on the power supply voltage (Vcc) of the power amplifier 12, and increases as the power supply voltage (Vcc) increases. In summary, the emitter current of the transistor T152 decreases as the power supply voltage (Vcc) increases, and increases as the reference current (Iref) increases.

From the above description, when the reference current (Iref) is constant, the sum of the emitter currents of the transistors T151 and T152 decreases as the power supply voltage (Vcc) increases. Therefore, in the bias circuit 15, the bias voltage (Vbe2) supplied to the power amplifier 12 increases as the power supply voltage (Vcc) increases.

The relationship between the bias voltage (Vbe2) and the power supply voltage (Vcc) will be described with reference to FIG. 4B. FIG. 4B is a diagram illustrating the relationship between the bias voltage (Vbe2) supplied from the bias circuit 15 according to this embodiment and the power supply voltage (Vcc). In FIG. 4B, the vertical axis represents the bias voltage (Vbe2), and the horizontal axis represents the power supply voltage (Vcc).

The bias circuit 15 can supply a bias voltage (Vbe21) (an example of a third bias voltage) to the power amplifier 12 when the power amplifier 12 is supplied with the power supply voltage (Vcc1). Furthermore, the bias circuit 15 can supply a bias voltage (Vbe22) (an example of a fourth bias voltage) higher than the bias voltage (Vbe21) to the power amplifier 12 when the power amplifier 12 is supplied with the power supply voltage (Vcc2) higher than the power supply voltage (Vcc1).

Similarly, when a power supply voltage (Vcc3) higher than the power supply voltage (Vcc2) is supplied to the power amplifier 12, the bias circuit 15 can supply a bias voltage (Vbe23) higher than the bias voltage (Vbe22) to the power amplifier 12. Furthermore, when a power supply voltage (Vcc4) higher than the power supply voltage (Vcc3) is supplied to the power amplifier 12, the bias circuit 15 can supply a bias voltage (Vbe24) higher than the bias voltage (Vbe23) to the power amplifier 12.

As described above, the bias circuit 15 can supply a higher bias voltage (Vbe2) to the power amplifier 12 as the power supply voltage (Vcc) supplied to the power amplifier 12 increases. In other words, the bias circuit 15 can supply the bias voltage (Vbe2) having a positive proportional relationship to the power supply voltage (Vcc) to the power amplifier 12. This positive proportional relationship can be determined by measuring the bias voltage (Vbe2) at at least three different levels of the power supply voltage (Vcc), as in the case of the negative proportional relationship.

In this embodiment, the bias voltage (Vbe2) is proportional to the power supply voltage (Vcc), but the relationship between the bias voltage (Vbe2) and the power supply voltage (Vcc) is not limited to being proportional. For example, the bias voltage (Vbe2) may increase in a stepwise or exponential manner as the power supply voltage (Vcc) increases. Furthermore, in a range of the power supply voltage (Vcc) that is not supplied to the power amplifier 12, the bias voltage (Vbe2) may decrease as the power supply voltage (Vcc) increases.

### 1.3 Implementation Example of Power Amplifier Circuit 1

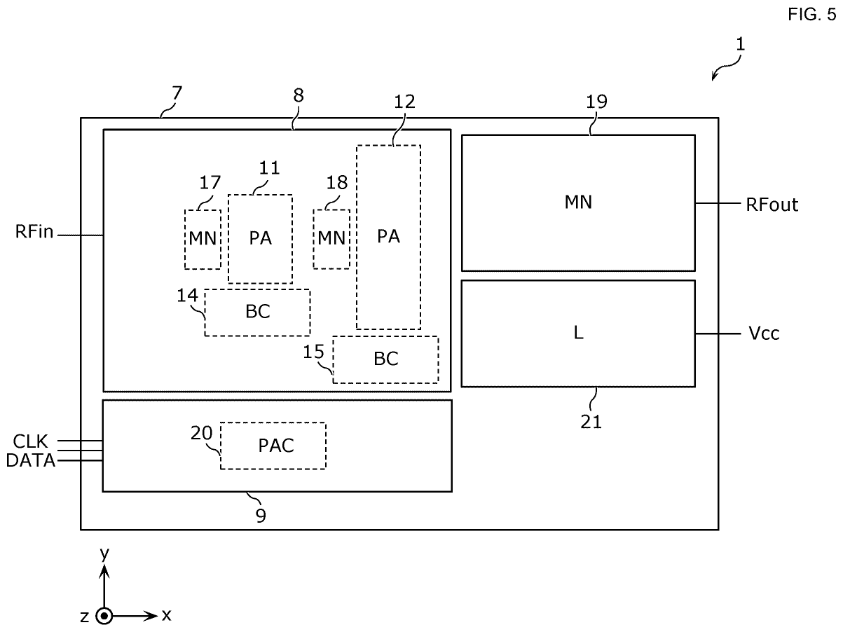

Next, an implementation example of the power amplifier circuit 1 according to this embodiment will be described with reference to FIG. 5. FIG. 5 is a layout diagram of the power amplifier circuit 1 according to this embodiment. In FIG. 5, multiple components are labeled with abbreviations (e.g., “PA”, “BC”, and the like) that indicate the functions of the components so that the layout relationship of the multiple components can be easily understood, but the actual circuit components may not be labeled with such abbreviations.

It is noted that FIG. 5 is an exemplary layout diagram, and the power amplifier circuit 1 may be implemented using any of a wide variety of circuit implementations and circuit technologies. Therefore, the description of the power amplifier circuit 1 provided below is not to be interpreted as limiting.

The power amplifier circuit 1 is mounted on a module substrate 7. Integrated circuits 8 and 9, the matching circuit 19 (MN), and the inductor 21 (L) are disposed on the module substrate 7.

The integrated circuit 8 includes the power amplifiers 11 and 12 (PA), the bias circuits 14 and 15 (BC), and the matching circuits 17 and 18 (MN). For example, silicon germanium (SiGe) or gallium arsenide (GaAs) can be used as the semiconductor material of the integrated circuit 8. For example, gallium nitride (GaN) or silicon carbide (SiC) may also be used as the semiconductor material of the integrated circuit 8.

The power amplifiers 11 and 12 can be constructed using heterojunction bipolar transistors (HBTs). The amplifying transistors of the power amplifiers 11 and 12 are not limited to HBTs. For example, the power amplifiers 11 and/or 12 may be constructed using high electron mobility transistors (HEMTs) or metal-semiconductor field effect transistors (MESFETs).

The bias circuit 14 is disposed close to the power amplifier 11. That is, the bias circuit 14 is disposed closer to the power amplifier 11 than the bias circuit 15. In other words, the power amplifier 11 is disposed closer to the bias circuit 14 than the power amplifier 12.

The bias circuit 15 is disposed close to the power amplifier 12. That is, the bias circuit 15 is disposed closer to the power amplifier 12 than the bias circuit 14. In other words, the power amplifier 12 is disposed closer to the bias circuit 15 than the power amplifier 11.

The integrated circuit 9 includes the PA control circuit 20 (PAC). As the semiconductor material of the integrated circuit 9, for example, single crystal silicon, GaN, or SiC can be used. The integrated circuit 9 is disposed next to the integrated circuit 8.

It is noted that the power amplifier circuit 1 is mounted on one side of the module substrate 7, but is not limited to this layout. For example, the power amplifier circuit 1 may be mounted on both sides of the module substrate 7 in an alternative aspect. In addition, the integrated circuit 8 may be divided into multiple integrated circuits. Furthermore, the integrated circuit 9 may be stacked on the integrated circuit 8, or conversely, the integrated circuit 8 may be stacked on the integrated circuit 9.

### 1.4 Power Amplification Method

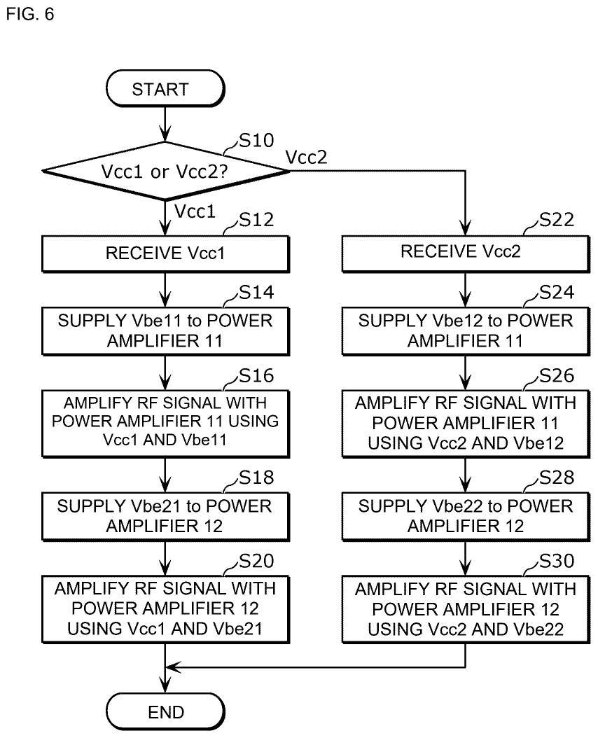

Next, a power amplification method according to this embodiment will be described with reference to FIG. 6. FIG. 6 is a flowchart illustrating the power amplification method according to this embodiment. It is noted that a case is assumed in FIG. 6 in which two discrete levels of power supply voltage (Vcc1 and Vcc2) are supplied to the power amplifier circuit 1.

First, when the power supply voltage (Vcc1) is supplied to the power amplifier circuit 1 (Vcc1 in S10), the bias circuits 14 and 15 receive the power supply voltage (Vcc1) (S12).

The bias circuit 14 supplies the bias voltage (Vbe11) based on the power supply voltage (Vcc1) to the power amplifier 11 (S14). The power amplifier 11 amplifies a radio frequency signal using the power supply voltage (Vcc1) and the bias voltage (Vbe11) (S16).

The bias circuit 15 supplies the bias voltage (Vbe21) based on the power supply voltage (Vcc1) to the power amplifier 12 (S18). The power amplifier 12 amplifies the radio frequency signal amplified by the power amplifier 11 using the power supply voltage (Vcc1) and the bias voltage (Vbe21) (S20).

When the power amplifier circuit 1 is supplied with the power supply voltage (Vcc2) (Vcc2 in S10), the bias circuits 14 and 15 receive the power supply voltage (Vcc2) higher than the power supply voltage (Vcc1) (S22).

The bias circuit 14 supplies the power amplifier 11 with the bias voltage (Vbe12) lower than the bias voltage (Vbe11) based on the power supply voltage (Vcc2) (S24). The power amplifier 11 amplifies the radio frequency signal using the power supply voltage (Vcc2) and the bias voltage (Vbe12) (S26).

The bias circuit 15 supplies the power amplifier 12 with the bias voltage (Vbe22) higher than the bias voltage (Vbe21) based on the power supply voltage (Vcc2) (S28). The power amplifier 12 amplifies the radio frequency signal amplified by the power amplifier 11 using a power supply voltage (Vcc2) and a bias voltage (Vbe22) (S30).

It is noted that the steps and the order of steps in FIG. 6 are merely examples, and the power amplification method is not limited to the flowchart in FIG. 6 as would be appreciated to one skilled in the art. For example, Steps S14 and S18 may be performed simultaneously, and Steps S24 and S28 may be performed simultaneously.

### 1.5 Gain of Power Amplifier Circuit 1

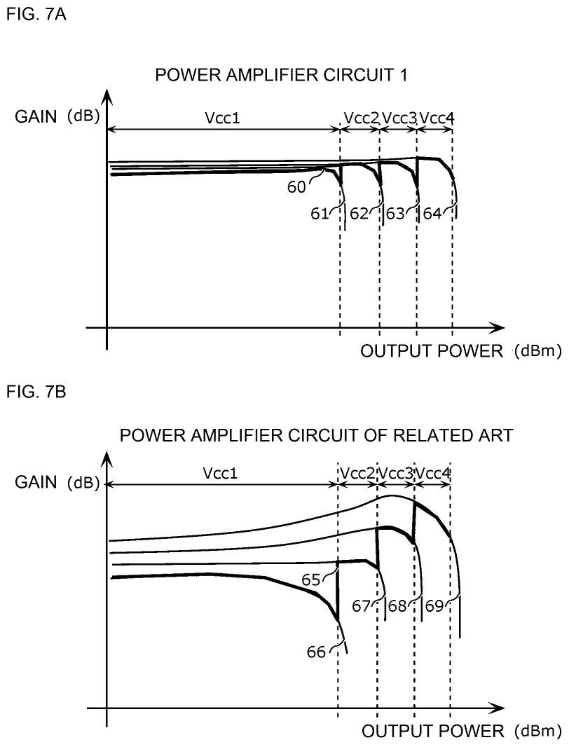

Next, the gain of the power amplifier circuit 1 as described above will be described with reference to FIG. 7A and FIG. 7B. FIG. 7A is a diagram illustrating the gain characteristics with respect to the output power of the power amplifier circuit 1 according to this embodiment. FIG. 7B is a diagram illustrating the gain characteristics with respect to the output power of a power amplifier circuit of the related art. In FIG. 7A and FIG. 7B, the vertical axis represents the gain of the power amplifier circuit, and the horizontal axis represents the output power of the power amplifier circuit.

It is noted that the power amplifier circuit of the related art refers to a power amplifier circuit having a bias circuit that supplies a fixed bias voltage to the power amplifiers 11 and 12 independent of the power supply voltage (Vcc).

In FIG. 7A, gains 61 to 64 represent the gains of the power amplifier circuit 1 at the power supply voltages (Vcc1 to Vcc4). Gain 60 represents the gain of the power amplifier circuit 1 when the power supply voltage (Vcc1 to Vcc4) is changed discretely in accordance with the output power.

In FIG. 7B, gains 66 to 69 represent the gains of the power amplifier circuit of the related art at the power supply voltages (Vcc1 to Vcc4). Gain 65 represents the gain of the power amplifier circuit of the related art when the power supply voltage (Vcc1 to Vcc4) is changed discretely in accordance with the output power.

As illustrated in FIGS. 7A and 7B, in this embodiment, the difference in gain characteristics (shape of the gain curve) in the saturation region at multiple discrete voltages (Vcc1 to Vcc4) can be suppressed more than was previously possible. Furthermore, in this embodiment, discontinuous changes in gain with respect to discrete changes in the power supply voltage (Vcc) can be suppressed more than was previously possible. As a result, the difficulty of DPD in the RFIC 3 can be reduced, and this can contribute to reducing the power consumption for DPD and/or reducing nonlinear distortion due to DPD.

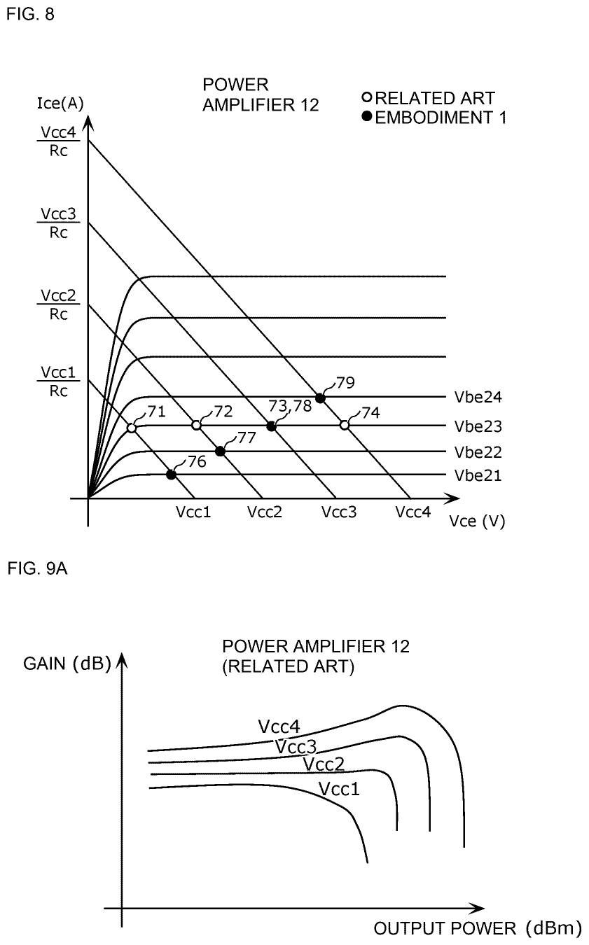

Next, the reason why the difference in gain characteristics in the saturation region at multiple discrete voltages and discontinuous changes in gain with respect to discrete changes in the power supply voltage can be suppressed in this embodiment will be described with reference to FIGS. 8 to 10B.

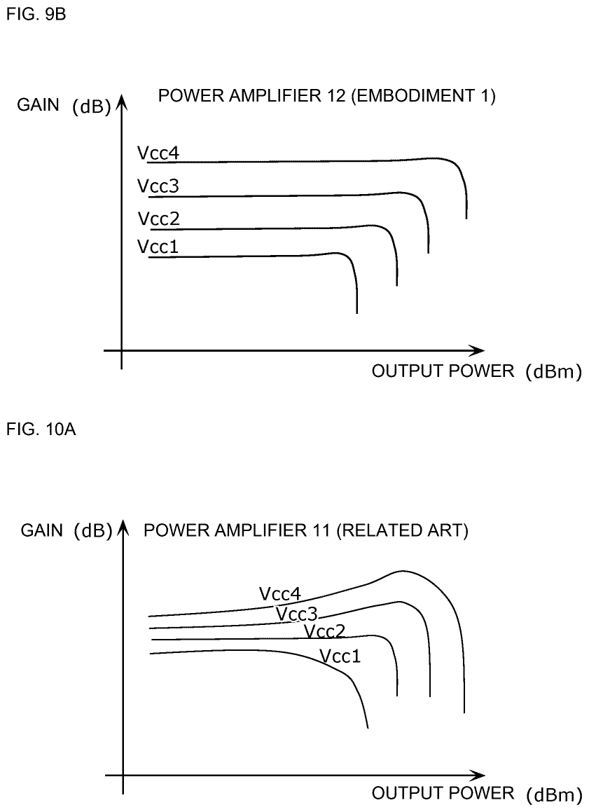

FIG. 8 is a diagram illustrating the operating points of the power amplifiers 12 according to Embodiment 1 and the related art. FIG. 9A is a diagram illustrating the gain characteristics with respect to the output power of the power amplifier 12 of the related art. FIG. 9B is a diagram illustrating the gain characteristics with respect to the output power of the power amplifier 12 according to Embodiment 1. In FIG. 8, the vertical axis represents the collector (emitter) current (Ice), and the horizontal axis represents the collector-emitter voltage (Vce). In FIG. 9A and FIG. 9B, the vertical axis represents the gain, and the horizontal axis represents the output power.

Operating points 71 to 74 represent operating points at respective power supply voltages of the power amplifier 12 of the related art in which the bias voltage (Vbe2) is fixed. Operating points 76 to 79 represent operating points at respective power supply voltages of the power amplifier 12 according to this embodiment in which a higher bias voltage (Vbe2) is supplied as the power supply voltage (Vcc) increases.

In the power amplifier 12 of the related art, the bias voltage (Vbe2) is constant at the voltage (Vbe23), and therefore when the power supply voltage (Vcc) changes, the ratio of the collector-emitter voltage (Vce) to the power supply voltage (Vcc) also changes significantly. For example, the ratio of the collector-emitter voltage (Vce) to the power supply voltage (Vcc1) at the operating point 71 at the power supply voltage (Vcc1) is lower than the ratio of the collector-emitter voltage (Vce) to the power supply voltage (Vcc4) at the operating point 74 at the power supply voltage (Vcc4). Therefore, the operation mode of the power amplifier 12 (e.g., from class AB to class A) also changes with the change in the power supply voltage (Vcc). As a result, as illustrated in FIG. 9A, the gain characteristics in the saturation region of the power amplifier 12 change with the multiple discrete voltages (Vcc1 to Vcc4) supplied to the power amplifier 12.

On the other hand, in the power amplifier 12 of this embodiment, when the power supply voltage (Vcc) is lowered, the bias voltage (Vbe2) is also lowered, and therefore even when the power supply voltage (Vcc) changes, the change in the ratio of the collector-emitter voltage (Vce) to the power supply voltage (Vcc) is suppressed. For example, the ratio of the collector-emitter voltage (Vce) at the operating point 76 at the power supply voltage (Vcc1) to the power supply voltage (Vcc1) is not significantly different from the ratio of the collector-emitter voltage (Vce) at the operating point 79 at the power supply voltage (Vcc4) to the power supply voltage (Vcc4). Therefore, a change in the operation mode of the power amplifier 12 due to a change in the power supply voltage (Vcc) is suppressed. As a result, as illustrated in FIG. 9B, the gain characteristics of the power amplifier 12 in the saturation region do not change with the multiple discrete voltages (Vcc1 to Vcc4) supplied to the power amplifier 12.

It is noted that, in the power amplifier 12 according to this embodiment, changes in the gain characteristics in the saturation region can be suppressed at multiple discrete voltages, but differences in gain in the linear region become large. Therefore, it is difficult to suppress discontinuous changes in the gain of the power amplifier circuit 1 with respect to discrete changes in the power supply voltage (Vcc) by only controlling the bias voltage of the power amplifier 12. Therefore, in this embodiment, the bias voltage (Vbe1) that decreases with an increase in the power supply voltage (Vcc) is supplied to the power amplifier 11.

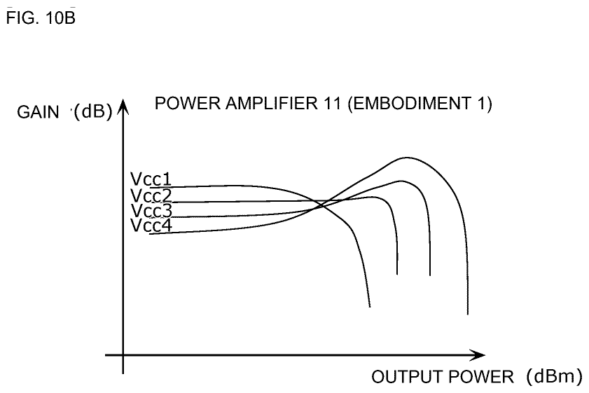

FIG. 10A is a diagram illustrating the gain characteristics with respect to the output power of the power amplifier 11 of the related art. FIG. 10B is a diagram illustrating the gain characteristics with respect to the output power of the power amplifier 11 according to Embodiment 1.

As illustrated in FIG. 10A, in the power amplifier 11 of the related art, the gain increases as the power supply voltage (Vcc) increases in the linear region. On the other hand, as illustrated in FIG. 10B, in the power amplifier 11 of this embodiment, the gain decreases as the power supply voltage (Vcc) increases in the linear region. This makes it possible to compensate for changes in gain in the linear region of the power amplifier 12 by using changes in gain in the linear region of the power amplifier 11. As a result, in this embodiment, as illustrated in FIG. 7A, it is possible to suppress discontinuous changes in the gain of the power amplifier circuit 1 in response to discrete changes in the power supply voltage (Vcc).

### 1.6 Technical Effects of Embodiment 1

As described above, the power amplifier circuit 1 according to this embodiment includes: the power amplifier 11 configured to amplify a radio frequency signal using multiple discrete voltages including a first power supply voltage (e.g., Vcc1) and a second power supply voltage (e.g., Vcc2) higher than the first power supply voltage; the power amplifier 12 configured to amplify the radio frequency signal amplified by the power amplifier 11 using multiple discrete voltages; the bias circuit 14 configured to supply a first bias voltage (e.g., Vbe11) to the power amplifier 11 when the first power supply voltage is supplied to the power amplifier 11 and to supply a second bias voltage (e.g., Vbe12) lower than the first bias voltage to the power amplifier 11 when the second power supply voltage is supplied to the power amplifier 11; and a bias circuit 15 configured to supply a third bias voltage (e.g., Vbe21) to the power amplifier 12 when the first power supply voltage is supplied to the power amplifier 12 and to supply a fourth bias voltage (e.g., Vbe22) higher than the third bias voltage to the power amplifier 12 when the second power supply voltage is supplied to the power amplifier 12.

Accordingly, a change in the voltage of the operating point with respect to the power supply voltage caused by a change in the power supply voltage can be suppressed by supplying a higher fourth bias voltage when a higher second power supply voltage is supplied to the power amplifier 12. Therefore, a change in the operation mode caused by a change in the power supply voltage can be suppressed, and a change in the gain characteristics in the saturation region of the power amplifier can be suppressed. As a result, the difficulty of DPD can be reduced, thereby contributing to reducing power consumption for DPD and/or reducing nonlinear distortion due to DPD. Furthermore, by supplying a lower second bias voltage when a higher second power supply voltage is supplied to the power amplifier 11, a change in gain in the linear region of the power amplifier 11 can compensate for a change in gain in the linear region of the power amplifier 12. Therefore, a change in gain with respect to a change in the power supply voltage in the linear region of the power amplifier circuit 1 can be suppressed, and a discontinuous change in the gain of the power amplifier circuit 1 with respect to a discrete change in the power supply voltage can be suppressed. As a result, the difficulty of DPD can be reduced, thereby contributing to reducing power consumption for DPD and/or reducing nonlinear distortion due to DPD.

Furthermore, for example, in the power amplifier circuit 1 according to this embodiment, the bias circuit 14 may be configured to supply a lower bias voltage (Vbe1) to the power amplifier 11 as the power supply voltage (Vcc) supplied to the power amplifier 11 increases, and the bias circuit 15 may be configured to supply a higher bias voltage (Vbe2) to the power amplifier 12 as the power supply voltage (Vcc) supplied to the power amplifier 12 increases.

This makes it possible to suppress changes in the voltage of the operating point relative to the power supply voltage due to changes in the power supply voltage even when more discrete voltages are supplied to the power amplifier circuit 1, and also suppresses discontinuous changes in the gain of the power amplifier circuit 1 relative to discrete changes in the power supply voltage. This makes it possible to reduce the difficulty of DPD and contribute to reducing power consumption for DPD and/or reducing nonlinear distortion due to DPD.

Furthermore, for example, in the power amplifier circuit 1 according to this embodiment, the power amplifier 11, the power amplifier 12, the bias circuit 14, and the bias circuit 15 may be included in one integrated circuit 8, the bias circuit 14 may be disposed closer to the power amplifier 11 than the bias circuit 15, and the bias circuit 15 may be disposed closer to the power amplifier 12 than the bias circuit 14.

This makes it possible to dispose the bias circuit 14 closer to the power amplifier 11, and the bias circuit 15 closer to the power amplifier 12. Therefore, the wiring length between the bias circuit 14 and the power amplifier 11 and the wiring length between the bias circuit 15 and the power amplifier 12 can be shortened. As a result, deterioration of the bias voltage (Vbe1) supplied from the bias circuit 14 to the power amplifier 11 and the bias voltage (Vbe2) supplied from the bias circuit 15 to the power amplifier 12 can be suppressed. In particular, since the bias voltages (Vbe1 and Vbe2) change in response to changes in the power supply voltage (Vcc), the effect of the parasitic impedance of the wiring is significant and shortening the wiring length is effective.

Furthermore, for example, in the power amplifier circuit 1 according to this embodiment, the power amplifier 11, the power amplifier 12, the bias circuit 14, and the bias circuit 15 may be included in one integrated circuit 8, the power amplifier 11 may be disposed closer to the bias circuit 14 than the power amplifier 12, and the power amplifier 12 may be disposed closer to the bias circuit 15 than the power amplifier 11.

In this way, the power amplifier 11 is disposed closer to the bias circuit 14, and the power amplifier 12 is disposed closer to the bias circuit 15. Therefore, the wiring length between the bias circuit 14 and the power amplifier 11 and the wiring length between the bias circuit 15 and the power amplifier 12 can be shortened. As a result, deterioration of the bias voltage (Vbe1) supplied from the bias circuit 14 to the power amplifier 11 and the bias voltage (Vbe2) supplied from the bias circuit 15 to the power amplifier 12 can be suppressed. In particular, since the bias voltages (Vbe1 and Vbe2) change in response to changes in the power supply voltage (Vcc), the effect of the parasitic impedance of the wiring is significant and shortening the wiring length is effective.

The power amplification method according to this embodiment is a power amplification method for amplifying a radio frequency signal using multiple discrete voltages. The power amplification method includes: receiving a first power supply voltage (e.g., Vcc1) included in the multiple discrete voltages (S12); supplying a first bias voltage (e.g., Vbe11) to the power amplifier 11 based on the first power supply voltage (S14); amplifying a first radio frequency signal in the power amplifier 11 using the first power supply voltage and the first bias voltage (S16); supplying a third bias voltage (e.g., Vbe21) to the power amplifier 12 based on the first power supply voltage (S18); amplifying the first radio frequency signal amplified by the power amplifier 11 in the power amplifier 12 using the first power supply voltage and the third bias voltage (S20); receiving a second power supply voltage (e.g., Vcc2) that is included in the multiple discrete voltages and is higher than the first power supply voltage (S22); supplying a second bias voltage (e.g., Vbe12) that is lower than the first bias voltage to the power amplifier 11 based on the second power supply voltage (S24); amplifying a second radio frequency signal in the power amplifier 11 using the second power supply voltage and the second bias voltage (S26); supplying a fourth bias voltage (e.g., Vbe22) that is higher than the third bias voltage to the power amplifier 12 based on the second power supply voltage (S28); and amplifying the second radio frequency signal amplified by the power amplifier 11 in the power amplifier 12 using the second power supply voltage and the fourth bias voltage (S30).

Accordingly, a change in the voltage of the operating point with respect to the power supply voltage caused by a change in the power supply voltage can be suppressed by supplying a higher fourth bias voltage when a higher second power supply voltage is supplied to the power amplifier 12. Therefore, a change in the operation mode caused by a change in the power supply voltage can be suppressed, and a change in the gain characteristics in the saturation region of the power amplifier can be suppressed. As a result, the difficulty of DPD can be reduced, thereby contributing to reducing power consumption for DPD and/or reducing nonlinear distortion due to DPD. Furthermore, when a higher second power supply voltage is supplied to the power amplifier 11, a lower second bias voltage is supplied, and thus a change in gain in the linear region of the power amplifier 12 can be compensated for by a change in gain in the linear region of the power amplifier 11. Therefore, a change in gain with respect to a change in the power supply voltage in the linear region of the power amplifier circuit 1 can be suppressed, and a discontinuous change in the gain of the power amplifier circuit 1 with respect to a discrete change in the power supply voltage can be suppressed. As a result, the difficulty of DPD can be reduced, thereby contributing to reducing power consumption for DPD and/or reducing nonlinear distortion due to DPD.

### Modification 1 of Embodiment 1

Next, Modification 1 of Embodiment 1 will be described. This modification mainly differs from Embodiment 1 in that the bias voltage supplied to the power amplifier 11 can be switched depending on the tracking mode. Hereafter, this modification will be described with reference to the drawings, focusing on the differences from Embodiment 1.

FIG. 2 is a circuit configuration diagram of a communication device 6A according to this modification. As illustrated in FIG. 2, the communication device 6A according to this modification is substantially the same as the communication device 6 according to Embodiment 1, except that the communication device 6A includes a power amplifier circuit 1A instead of the power amplifier circuit 1, and therefore the description thereof is omitted. The power amplifier circuit 1A according to this modification is substantially the same as the power amplifier circuit 1 according to Embodiment 1, except that the power amplifier circuit 1A includes a bias circuit 14A instead of the bias circuit 14, and therefore the description thereof is omitted.

### 1.7 Circuit Configuration of Bias Circuit 14A

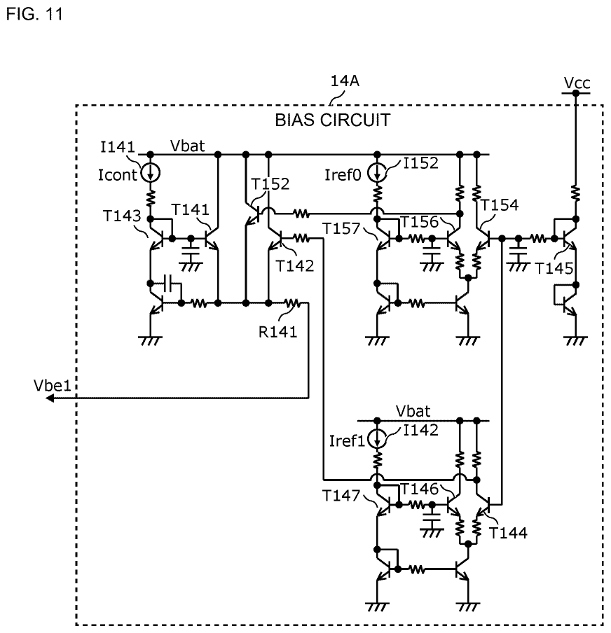

The circuit configuration of the bias circuit 14A according to this modification will be described with reference to FIG. 11. FIG. 11 is a circuit diagram of the bias circuit 14A according to this modification.

It is noted that FIG. 11 depicts an exemplary circuit configuration, and the bias circuit 14A can be implemented using any of a wide variety of circuit implementations and circuit technologies. Therefore, the description of the bias circuit 14A provided below should not be interpreted as limiting.

The bias circuit 14A has a circuit configuration that is a combination of the bias circuits 14 and 15. Specifically, the bias circuit 14A includes transistors T141 to T147, T152, T154, T156, and T157, a resistor R141, a constant current source I141, and reference current sources I142 and I152.

In this modification, the reference current sources I142 and I152 are controlled according to a tracking mode. Specifically, when the D-ET mode and the SPT mode are applied to the power amplifier circuit 1A, the reference current source I142 is turned on and the reference current source I152 is turned off. That is, in the D-ET mode and the SPT mode, a reference current (Iref0) is output from the reference current source I142, and a reference current (Iref1) is not output from the reference current source I152. On the other hand, when the APT mode is applied to the power amplifier circuit 1A, the reference current source I142 is turned off, and the reference current source 1152 is turned on. That is, in the APT mode, the reference current (Iref0) is not output from the reference current source I142, and the reference current (Iref1) is output from the reference current source I152.

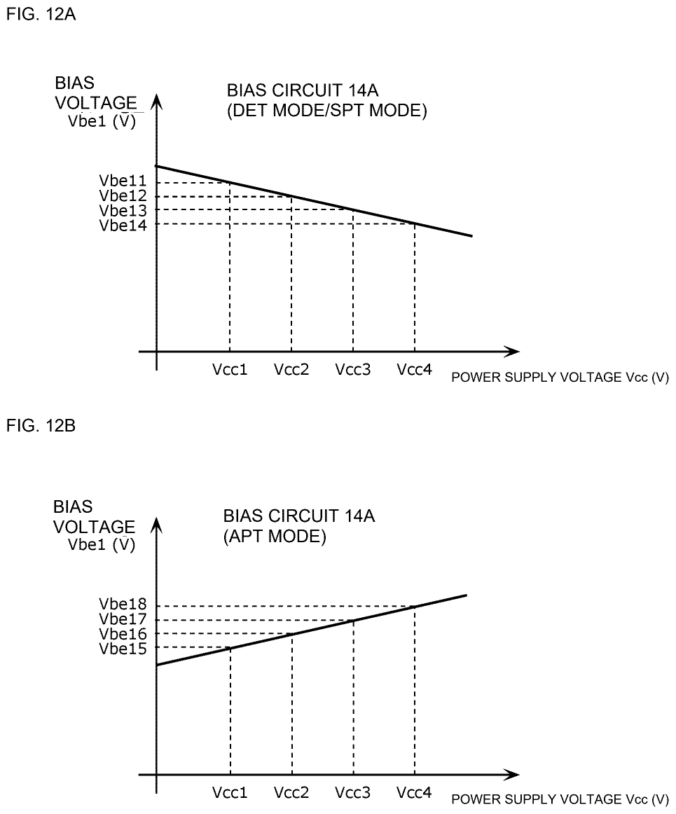

This allows the operation of the bias circuit 14A to be switched between the DET mode or the SPT mode and the APT mode. Next, the operation of the bias circuit 14A will be described with reference to FIG. 12A and FIG. 12B.

FIG. 12A and FIG. 12B are diagrams illustrating the relationship between the bias voltage (Vbe1) supplied from the bias circuit 14A according to this modification and the power supply voltage (Vcc). In FIG. 12A and FIG. 12B, the vertical axis represents the bias voltage (Vbe1), and the horizontal axis represents the power supply voltage (Vcc).

When the D-ET mode or the SPT mode is applied to the power amplifier circuit 1A, as illustrated in FIG. 12A, the bias circuit 14A can supply a bias voltage (Vbe11) (an example of a first bias voltage) to the power amplifier 11 when a power supply voltage (Vcc1) (an example of a first power supply voltage) is supplied to the power amplifier 11. When a power supply voltage (Vcc2) (an example of a second power supply voltage) higher than the power supply voltage (Vcc1) is supplied to the power amplifier 11, the bias circuit 14A can supply a bias voltage (Vbe12) (an example of a second bias voltage) lower than the bias voltage (Vbe11) to the power amplifier 11.

Similarly, when a power supply voltage (Vcc3) higher than the power supply voltage (Vcc2) is supplied to the power amplifier 11, the bias circuit 14A can supply a bias voltage (Vbe13) lower than the bias voltage (Vbe12) to the power amplifier 11. Furthermore, when a power supply voltage (Vcc4) higher than the power supply voltage (Vcc3) is supplied to the power amplifier 11, the bias circuit 14A can supply a bias voltage (Vbe14) lower than the bias voltage (Vbe13) to the power amplifier 11.

On the other hand, when the APT mode is applied to the power amplifier circuit 1A, as illustrated in FIG. 12B, the bias circuit 14A can supply a bias voltage (Vbe15) (an example of a fifth bias voltage) to the power amplifier 11 when a power supply voltage (Vcc1) is supplied to the power amplifier 11. Furthermore, the bias circuit 14A can supply a bias voltage (Vbe16) (an example of a sixth bias voltage) higher than the bias voltage (Vbe15) to the power amplifier 11 when a power supply voltage (Vcc2) higher than the power supply voltage (Vcc1) is supplied to the power amplifier 11.

Similarly, the bias circuit 14A can supply a bias voltage (Vbe17) higher than the bias voltage (Vbe16) to the power amplifier 11 when a power supply voltage (Vcc3) higher than the power supply voltage (Vcc2) is supplied to the power amplifier 11. Furthermore, when a power supply voltage (Vcc4) higher than the power supply voltage (Vcc3) is supplied to the power amplifier 11, the bias circuit 14A can supply a bias voltage (Vbe18) higher than the bias voltage (Vbe17) to the power amplifier 11.

As described above, when the D-ET mode or SPT mode is applied to the power amplifier 11, the bias circuit 14A can supply a lower bias voltage (Vbe1) to the power amplifier 11 as the power supply voltage (Vcc) supplied to the power amplifier 11 increases. That is, in the D-ET mode or SPT mode, the bias circuit 14A can supply a bias voltage (Vbe1) having a negative proportional relationship with the power supply voltage (Vcc) to the power amplifier 11. On the other hand, when the APT mode is applied to the power amplifier 11, the bias circuit 14A can supply a higher bias voltage (Vbe1) to the power amplifier 11 as the power supply voltage (Vcc) supplied to the power amplifier 11 increases. That is, in the APT mode, the bias circuit 14A can supply a bias voltage (Vbe1) having a positive proportional relationship with the power supply voltage (Vcc) to the power amplifier 11.

It is noted that in this modification, the bias voltage (Vbe1) has a positive or negative proportional relationship with the power supply voltage (Vcc), but the relationship between the bias voltage (Vbe1) and the power supply voltage (Vcc) is not limited to a proportional relationship. For example, the bias voltage (Vbe1) may change in a stepwise or exponential manner with respect to changes in the power supply voltage (Vcc). Furthermore, in a range of the power supply voltage (Vcc) not supplied to the power amplifier 11, the bias voltage (Vbe1) may change in the opposite manner to the range of the power supply voltage (Vcc) supplied to the power amplifier 11. In addition, the bias voltage (Vbe1) may be fixed regardless of the power supply voltage (Vcc).

### 1.8 Technical Effects of Modification 1 of Embodiment 1

As described above, in the power amplifier circuit 1A according to this modification, the bias circuit 14A may be configured to switch the bias voltage supplied to the power amplifier 11 depending on the tracking mode applied to the power amplifier 11. When the D-ET mode or the SPT mode is applied to the power amplifier 11, the bias circuit 14A may be configured to supply a first bias voltage (e.g., Vbe11) to the power amplifier 11 when a first power supply voltage (e.g., Vcc1) is supplied to the power amplifier 11, and to supply a second bias voltage (e.g., Vbe12) lower than the first bias voltage to the power amplifier 11 when a second power supply voltage (e.g., Vcc2) is supplied to the power amplifier 11. When the APT mode is applied to the power amplifier 11, the bias circuit 14A may be configured to supply a fifth bias voltage (e.g., Vbe15) to the power amplifier 11 when the first power supply voltage is supplied to the power amplifier 11, and to supply a sixth bias voltage (e.g., Vbe16) higher than the fifth bias voltage to the power amplifier 11 when the second power supply voltage is supplied to the power amplifier 11.

Accordingly, in the D-ET mode or SPT mode, bias voltages (Vbe1 and Vbe2), as in the case of the power amplifier circuit 1 according to Embodiment 1, are supplied to the power amplifiers 11 and 12, and therefore the difficulty of DPD can be reduced, thereby contributing to reducing power consumption for DPD and/or reducing nonlinear distortion due to DPD. On the other hand, in the APT mode, when a higher second power supply voltage is supplied to the power amplifier 12, a higher sixth bias voltage is supplied, and therefore the linearity of the power amplifier 11 can be improved. In the APT mode, the power supply voltage changes on a frame-by-frame basis, and the changes in the power supply voltage are slower than in the D-ET mode and SPT mode. Therefore, an increase in the difficulty of DPD due to gain fluctuations in the linear region is also suppressed.

For example, in the power amplifier circuit 1A according to this modification, when the D-ET mode or the SPT mode is applied to the power amplifier 11, the bias circuit 14A may be configured to supply a lower bias voltage (Vbe1) to the power amplifier 11 as the power supply voltage (Vcc) supplied to the power amplifier 11 increases, and when the APT mode is applied to the power amplifier 11, the bias circuit 14A may be configured to supply a higher bias voltage (Vbe1) to the power amplifier 11 as the power supply voltage (Vcc) supplied to the power amplifier 11 increases.

This makes it possible to reduce the difficulty of DPD even when more discrete voltages are supplied to the power amplifier circuit 1A, thereby contributing to reducing the power consumption for DPD and/or reducing nonlinear distortion due to DPD.

### Modification 2 of Embodiment 1

Next, Modification 2 of Embodiment 1 will be described. This modification mainly differs from Embodiment 1 in that the power amplifier circuit is a Doherty amplifier circuit. Hereafter, this modification will be described with reference to the drawings, focusing on the differences from Embodiment 1.

The circuit configuration of a communication device 6B according to this modification is substantially the same as that of the communication device 6 according to Embodiment 1, except that a power amplifier circuit 1B is provided instead of the power amplifier circuit 1, and therefore the description thereof will be omitted.

### 1.9 Circuit Configuration of Power Amplifier Circuit 1B

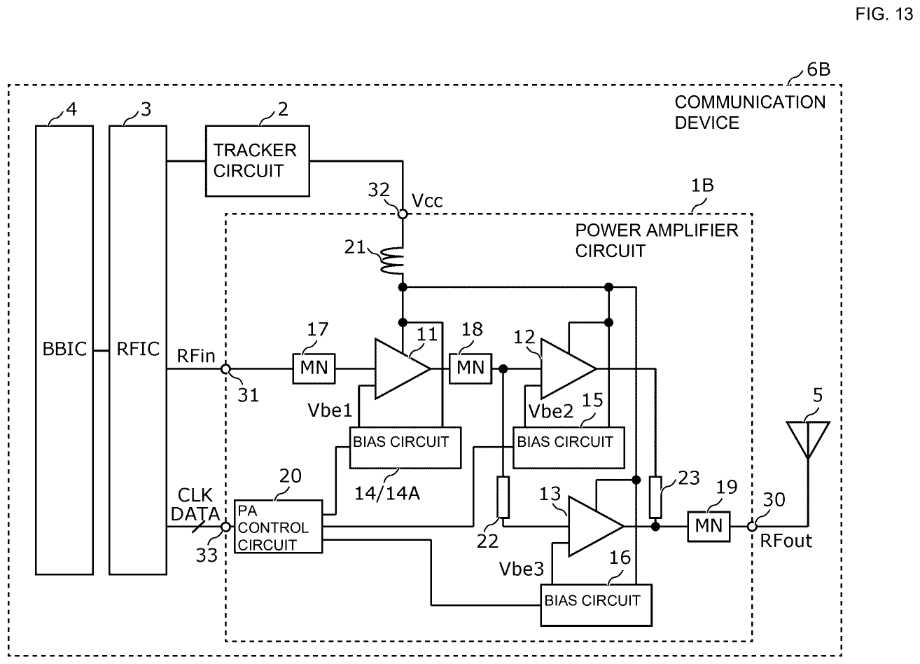

The circuit configuration of the power amplifier circuit 1B according to this modification will be described with reference to FIG. 13. FIG. 13 is a circuit configuration diagram of the communication device 6B according to this modification.

The power amplifier circuit 1B is a multi-stage amplifier circuit and is a Doherty amplifier circuit. The power amplifier circuit 1B includes power amplifiers 11 to 13, bias circuits 14 to 16, matching circuits (matching networks) 17 to 19, a PA control circuit 20, an inductor 21, and phase shift circuits 22 and 23.

According to an exemplary aspect, the term “Doherty amplifier circuit” refers to an amplifier circuit that achieves high efficiency by using multiple amplifiers as a carrier amplifier and a peak amplifier. Moreover, the term “carrier amplifier” refers to an amplifier, in the Doherty amplifier circuit, that operates regardless of whether the power of the radio frequency signal (input) is low or high. The term “peak amplifier” refers to an amplifier, in the Doherty amplifier circuit, that mainly operates when the power of the radio frequency signal (input) is high. Therefore, when the input power of the radio frequency signal is low, the radio frequency signal is mainly amplified by the carrier amplifier, and when the input power of the radio frequency signal is high, the radio frequency signal is amplified by the carrier amplifier and the peak amplifier and the resulting signals are then combined. With such an operation, in the Doherty amplifier circuit, the load impedance seen from the carrier amplifier at a low output power increases, and the efficiency at a low output power is improved.

The power amplifier 11 is an example of a “first power amplifier” according to the exemplary aspect and is connected between the radio-frequency input terminal 31 and the power amplifier 12. Specifically, an input terminal of the power amplifier 11 is connected to the radio-frequency input terminal 31 via the matching circuit 17. The output terminal of the power amplifier 11 is connected to the input terminal of the power amplifier 12 via a matching circuit 18 and is connected to the input terminal of the power amplifier 13 via the matching circuit 18 and the phase shift circuit 22. Furthermore, the power amplifier 11 is connected to the bias circuit 14, and is connected to a power supply voltage terminal 32 via the inductor 21. As a result, the power amplifier 11 can amplify a radio frequency signal (RFin) supplied from the RFIC 3 using a bias voltage (Vbe1) supplied from the bias circuit 14 and the power supply voltage (Vcc) supplied from the tracker circuit 2.

The power amplifier 12 is an example of a “second power amplifier” according to the exemplary aspect and is a carrier amplifier. The power amplifier 12 is connected between the power amplifier 11 and the antenna connection terminal 30. Specifically, the input terminal of the power amplifier 12 is connected to the output terminal of the power amplifier 11 via the matching circuit 18, and the output terminal of the power amplifier 12 is connected to the antenna connection terminal 30 via the phase shift circuit 23 and the matching circuit 19. Furthermore, the power amplifier 12 is connected to the bias circuit 15, and is connected to the power supply voltage terminal 32 via the inductor 21. This allows the power amplifier 12 to amplify at least part of the radio frequency signal amplified by the power amplifier 11 using the bias voltage (Vbe2) supplied from the bias circuit 15 and the power supply voltage (Vcc) supplied from the tracker circuit 2.

The power amplifier 13 is an example of a “third power amplifier” and is a peak amplifier according to the exemplary aspect. The power amplifier 13 is connected between the power amplifier 11 and the antenna connection terminal 30. Specifically, the input terminal of the power amplifier 13 is connected to the output terminal of the power amplifier 11 via the phase shift circuit 22 and the matching circuit 18, and the output terminal of the power amplifier 13 is connected to the antenna connection terminal 30 via the matching circuit 19. Furthermore, the power amplifier 13 is connected to the bias circuit 16 and to the power supply voltage terminal 32 via the inductor 21. This allows the power amplifier 13 to amplify part of the radio frequency signal amplified by the power amplifier 11 using the bias voltage (Vbe3) supplied from the bias circuit 16 and the power supply voltage (Vcc) supplied from the tracker circuit 2.

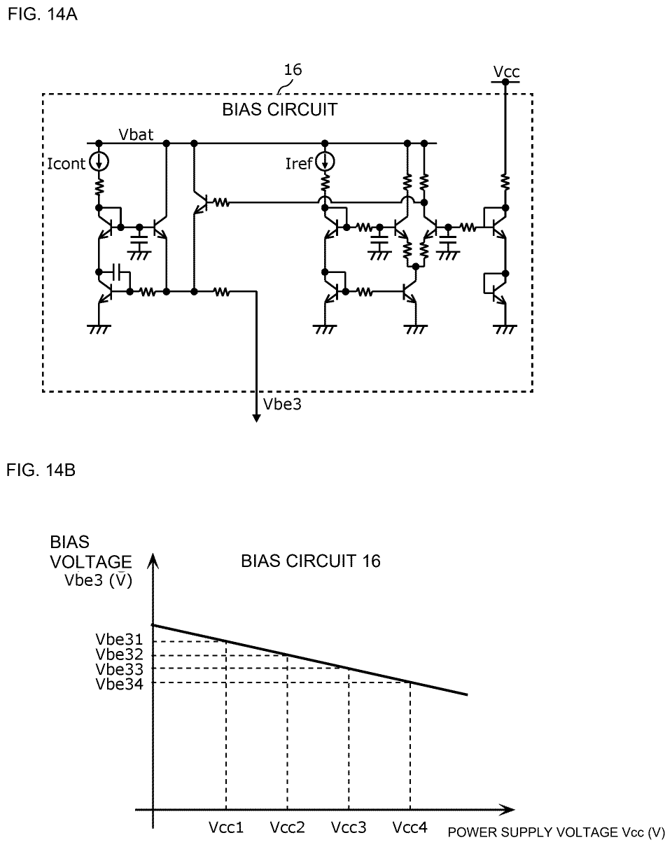

The bias circuit 16 is an example of a “third bias circuit” according to the exemplary aspect and is connected to the power amplifier 13. The bias circuit 16 can supply a bias voltage (Vbe3) to the power amplifier 13. The bias circuit 16 can change the bias voltage (Vbe3) in accordance with the power supply voltage (Vcc) supplied to the power amplifier 13. Details of the bias circuit 16 and the bias voltage (Vbe3) will be described later with reference to FIG. 14A and FIG. 14B.

The phase shift circuit 22 is connected between the output terminal of the power amplifier 11 and the input terminal of the power amplifier 13 and can shift the phase of part of the radio frequency signal amplified by the power amplifier 11 by −90 degrees (delay by 90 degrees).

The phase shift circuit 23 is connected between the output terminal of the power amplifier 12 and the antenna connection terminal 30 and can shift the phase of the radio frequency signal amplified by the power amplifier 12 by −90 degrees (delay by 90 degrees).

Each of the phase shift circuits 22 and 23 can be, for example, a quarter-wave transmission line. The phase shift circuits 22 and/or 23 may include an inductor and/or a capacitor. This enables the line lengths to be shortened by the phase shift circuits 22 and/or 23.

It is noted that in the power amplifier circuit 1B according to this modification, the output signals of the two power amplifiers 12 and 13 are combined in phase with each other, but this configuration may be varied. For example, the output signals of the two power amplifiers 12 and 13 may be combined with each other with opposite phases using a transformer. In this case, the phase shift circuit 23 may be connected between the output terminal of the power amplifier 13 and the transformer.

### 1.9.1 Circuit Configuration of Bias Circuit 16

The circuit configuration of the bias circuit 16 according to this modification will be described with reference to FIG. 14A. FIG. 14A is a circuit configuration diagram of the bias circuit 16 according to this modification.

It is noted that FIG. 14A depicts an exemplary circuit configuration, and the bias circuit 16 may be implemented using any of a wide variety of circuit implementations and circuit technologies. Therefore, the description of the bias circuit 16 provided below should not be interpreted as limiting.

As illustrated in FIG. 14A, the bias circuit 16 has the same circuit configuration as the bias circuit 14. Therefore, detailed description of the circuit configuration of the bias circuit 16 is omitted.

FIG. 14B is a diagram illustrating the relationship between the bias voltage (Vbe3) supplied from the bias circuit 16 according to this modification and the power supply voltage (Vcc). In FIG. 14B, the vertical axis represents the bias voltage (Vbe3), and the horizontal axis represents the power supply voltage (Vcc).

The bias circuit 16 can supply a bias voltage (Vbe31) (an example of a seventh bias voltage) to the power amplifier 13 when a power supply voltage (Vcc1) (an example of a first power supply voltage) is supplied to the power amplifier 13. Furthermore, when a power supply voltage (Vcc2) (an example of a second power supply voltage) higher than the power supply voltage (Vcc1) is supplied to the power amplifier 13, the bias circuit 16 can supply a bias voltage (Vbe32) (an example of an eighth bias voltage) lower than the bias voltage (Vbe31) to the power amplifier 13.

Similarly, when a power supply voltage (Vcc3) higher than the power supply voltage (Vcc2) is supplied to the power amplifier 13, the bias circuit 16 can supply a bias voltage (Vbe33) lower than the bias voltage (Vbe32) to the power amplifier 13. Furthermore, when a power supply voltage (Vcc4) higher than the power supply voltage (Vcc3) is supplied to the power amplifier 13, the bias circuit 16 can supply a bias voltage (Vbe34) lower than the bias voltage (Vbe33) to the power amplifier 13.

As described above, the bias circuit 16 can supply the power amplifier 13 with a lower bias voltage (Vbe3) as the power supply voltage (Vcc) supplied to the power amplifier 13 increases. In other words, the bias circuit 16 can supply the power amplifier 13 with a bias voltage (Vbe3) having a negative proportional relationship with the power supply voltage (Vcc).

It is noted that in this modification, the bias voltage (Vbe3) is proportional to the power supply voltage (Vcc), but the relationship between the bias voltage (Vbe3) and the power supply voltage (Vcc) is not limited to being proportional. For example, the bias voltage (Vbe3) may decrease in a stepwise or exponential manner as the power supply voltage (Vcc) increases. In addition, in a range of the power supply voltage (Vcc) that is not supplied to the power amplifier 13, the bias voltage (Vbe3) may increase as the power supply voltage (Vcc) increases.

### 1.10 Technical Effects of Modification 2 of Embodiment 1

As described above, the power amplifier circuit 1B according to this modification may be a Doherty amplifier circuit and may further include a power amplifier 13 as a peak amplifier, and the power amplifier 12 may be a carrier amplifier.

In addition to the power-added efficiency being improved by the Doherty amplifier circuit, this can contribute to reducing power consumption for DPD and/or reducing nonlinear distortion due to DPD, similarly to the power amplifier circuit 1 according to Embodiment 1.

Furthermore, for example, the power amplifier circuit 1B according to this modification may further include the bias circuit 16 configured to supply a seventh bias voltage (e.g., Vbe31) to the power amplifier 13 when a first power supply voltage (e.g., Vcc1) is supplied to the power amplifier 13, and to supply an eighth bias voltage (e.g., Vbe32) lower than the seventh bias voltage to the power amplifier 13 when a second power supply voltage (e.g., Vcc2) is supplied to the power amplifier 13.

Accordingly, when a higher second power supply voltage is supplied to the power amplifier 13, a lower eighth bias voltage is supplied, and therefore the rising output of the peak amplifier can be adjusted in accordance with an increase in the saturation output of the carrier amplifier, and the back-off region of the Doherty amplifier circuit can be optimized to improve the power added efficiency.

Furthermore, for example, in the power amplifier circuit 1B according to this modification, the bias circuit 16 may be configured to supply a lower bias voltage (Vbe3) to the power amplifier 13 as the power supply voltage (Vcc) supplied to the power amplifier 13 increases.

Accordingly, even when more discrete voltages are supplied to the power amplifier circuit 1B, the back-off region of the Doherty amplifier circuit can be optimized to improve the power added efficiency.

### Exemplary Embodiment 2

Next, Embodiment 2 will be described. In this embodiment, the main difference from Embodiment 1 is that the attenuation of a variable attenuator is changed instead of changing the bias voltage (Vbe1) of the power amplifier 11 according to the power supply voltage (Vcc). Hereafter, this embodiment is described with reference to the drawings, focusing on the differences from Embodiment 1.

The circuit configuration of a communication device 6C according to this embodiment is substantially the same as that of the communication device 6 according to Embodiment 1, except that the communication device 6C includes a power amplifier circuit 1C instead of the power amplifier circuit 1, and therefore the description thereof is omitted.

### 2.1 Circuit Configuration of Power Amplifier Circuit 1C

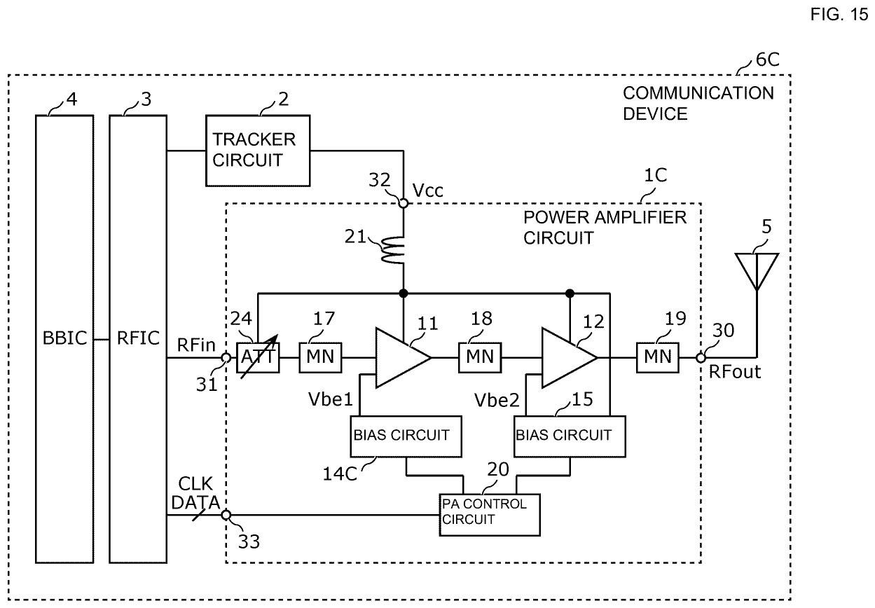

The circuit configuration of the power amplifier circuit 1C according to this embodiment will be described with reference to FIG. 15. FIG. 15 is a circuit configuration diagram of the communication device 6C according to this embodiment.

The power amplifier circuit 1C includes power amplifiers 11 and 12, bias circuits 14C and 15, matching circuits (matching networks) 17 to 19, a PA control circuit 20, an inductor 21, and a variable attenuation circuit 24.

The bias circuit 14C is an example of a “first bias circuit” according to the exemplary aspect and is connected to the power amplifier 11. The bias circuit 14C can supply a bias voltage (Vbe1) to the power amplifier 11.

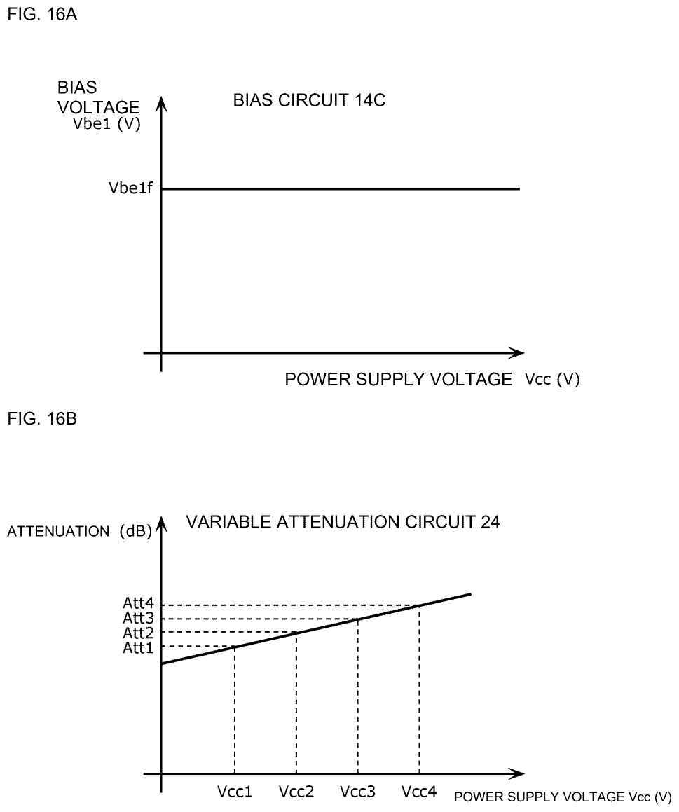

Specifically, for example, as illustrated in FIG. 16A, the bias circuit 14C can supply a fixed bias voltage (Vbe1f) to the power amplifier 11 regardless of the power supply voltage (Vcc). Substantially the same circuit configuration as that of a bias circuit of the related art can be used for the bias circuit 14C, and therefore illustration and description thereof are omitted.

The bias circuit 15 is an example of a “second bias circuit” according to the exemplary aspect and is connected to the power amplifier 12. The bias circuit 15 can supply a bias voltage (Vbe2) to the power amplifier 12. The bias circuit 15 can change the bias voltage (Vbe2) in accordance with the power supply voltage (Vcc) supplied to the power amplifier 12. Details of the bias circuit 15 and the bias voltage (Vbe2) are substantially the same as those in Embodiment 1, except that the bias voltage (Vbe21) is an example of the first bias voltage and the bias voltage (Vbe22) is an example of the second bias voltage, and therefore description thereof is omitted.

The variable attenuation circuit 24 is connected between the radio-frequency input terminal 31 and the input terminal of the power amplifier 11. Specifically, one end of the variable attenuation circuit 24 is connected to the radio-frequency input terminal 31, and the other end of the variable attenuation circuit 24 is connected to the input terminal of the power amplifier 11 via the matching circuit 17. Furthermore, the variable attenuation circuit 24 is connected to the power supply voltage terminal 32 via the inductor 21. The variable attenuation circuit 24 may be connected between the output terminal of the power amplifier 11 and the input terminal of the power amplifier 12.

The variable attenuation circuit 24 can change the attenuation thereof depending on the power supply voltage (Vcc). Here, the attenuation is expressed as a value obtained by inverting the sign of the common logarithm of the ratio of the output power to the input power. Therefore, the attenuation can be determined by measuring the input power and the output power.

Next, the relationship between the attenuation of the variable attenuation circuit 24 and the power supply voltage (Vcc) will be described with reference to FIG. 16B. FIG. 16B is a diagram illustrating the relationship between the attenuation of the variable attenuation circuit 24 according to this embodiment and the power supply voltage (Vcc). In FIG. 16B, the vertical axis represents the attenuation, and the horizontal axis represents the power supply voltage.

The variable attenuation circuit 24 can be adjusted to an attenuation (Att1) (an example of a first attenuation) when a power supply voltage (Vcc1) is supplied to the power amplifier circuit 1C. Furthermore, the variable attenuation circuit 24 can be adjusted to an attenuation (Att2) (an example of a second attenuation) greater than the attenuation (Att1) when a power supply voltage (Vcc2) higher than the power supply voltage (Vcc1) is supplied to the power amplifier circuit 1C.

Similarly, the variable attenuation circuit 24 can be adjusted to an attenuation (Att3) greater than the attenuation (Att2) when a power supply voltage (Vcc3) higher than the power supply voltage (Vcc2) is supplied to the power amplifier circuit 1C. Furthermore, the variable attenuation circuit 24 can be adjusted to an attenuation (Att4) greater than the attenuation (Att3) when a power supply voltage (Vcc4) higher than the power supply voltage (Vcc3) is supplied to the power amplifier circuit 1C.

As described above, the variable attenuation circuit 24 can be adjusted to a greater attenuation as the power supply voltage (Vcc) supplied to the power amplifier circuit 1C increases. In other words, the variable attenuation circuit 24 can be adjusted to an attenuation having a positive proportional relationship with the power supply voltage (Vcc).

It is noted that, in this embodiment, the attenuation of the variable attenuation circuit 24 is proportional to the power supply voltage (Vcc), but the relationship between the attenuation and the power supply voltage (Vcc) is not limited to being proportional. For example, the attenuation may increase in a stepwise or exponential manner as the power supply voltage (Vcc) increases. In addition, in a range of the power supply voltage (Vcc) not supplied to the power amplifier circuit 1C, the attenuation of the variable attenuation circuit 24 may decrease as the power supply voltage (Vcc) increases.

### 2.2 Implementation Example of Power Amplifier Circuit 1C

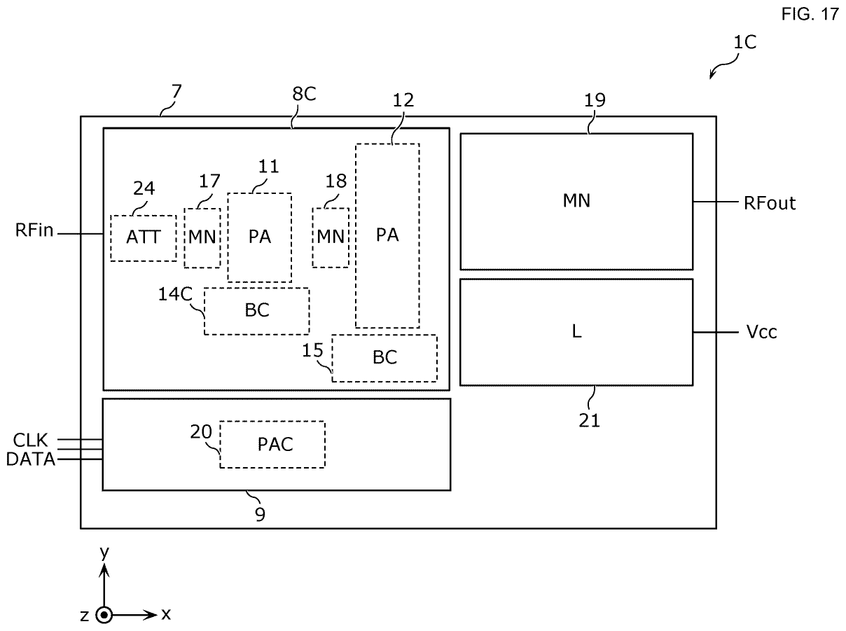

Next, an implementation example of the power amplifier circuit 1C according to this embodiment will be described with reference to FIG. 17. FIG. 17 is a layout diagram of the power amplifier circuit 1C according to this embodiment. In FIG. 17, multiple components are labeled with abbreviations (e.g., “PA”, “BC”, and the like) that indicate the functions of the components so that the layout relationship of the multiple components can be easily understood, but the actual circuit components do not need to be labeled with such abbreviations.

It is noted that FIG. 17 is an exemplary layout diagram, and the power amplifier circuit 1C can be implemented using any of a wide variety of circuit implementations and circuit technologies. Therefore, the description of the power amplifier circuit 1C provided below is not to be interpreted as limiting.

The power amplifier circuit 1C is mounted on a module substrate 7. Integrated circuits 8C and 9, the matching circuit 19 (MN), and the inductor 21 (L) are disposed on the module substrate 7.

The integrated circuit 8C includes the power amplifiers 11 and 12 (PA), the bias circuits 14C and 15 (BC), the matching circuits 17 and 18 (MN), and the variable attenuation circuit 24 (ATT). The semiconductor material of the integrated circuit 8C may be the same as or similar to that of the integrated circuit 8 of Embodiment 1.

The bias circuit 14C is disposed near the power amplifier 11. That is, the bias circuit 14C is disposed closer to the power amplifier 11 than the bias circuit 15. In other words, the power amplifier 11 is disposed closer to the bias circuit 14C than the power amplifier 12.

The bias circuit 15 is disposed close to the power amplifier 12. That is, the bias circuit 15 is disposed closer to the power amplifier 12 than the bias circuit 14C. In other words, the power amplifier 12 is disposed closer to the bias circuit 15 than the power amplifier 11.

It is noted that the power amplifier circuit 1C is mounted on one side of the module substrate 7 but is not limited to this layout. For example, the power amplifier circuit 1C may be mounted on both sides of the module substrate 7. In addition, the integrated circuit 8C may be divided into multiple integrated circuits. Furthermore, the integrated circuit 9 may be stacked on the integrated circuit 8C, or conversely, the integrated circuit 8C may be stacked on the integrated circuit 9.

### 2.3 Technical Effects of Embodiment 2

As described above, the power amplifier circuit 1C according to this embodiment includes: the power amplifier 11 configured to amplify a radio frequency signal using multiple discrete voltages including a first power supply voltage (e.g., Vcc1) and a second power supply voltage (e.g., Vcc2) higher than the first power supply voltage; the power amplifier 12 configured to amplify the radio frequency signal amplified by the power amplifier 11 using multiple discrete voltages; the bias circuit 14C configured to supply a bias voltage (Vbe1) to the power amplifier 11; the bias circuit 15 configured to supply a first bias voltage (e.g., Vbe21) to the power amplifier 12 when the first power supply voltage is supplied to the power amplifier 12, and to supply a second bias voltage (e.g., Vbe22) higher than the first bias voltage to the power amplifier 12 when the second power supply voltage is supplied to the power amplifier 12; and the variable attenuation circuit 24 connected to the input terminal of the power amplifier 11 or connected between the output terminal of the power amplifier 11 and the input terminal of the power amplifier 12. The variable attenuation circuit 24 is adjusted to a first attenuation (e.g., Att1) when the first power supply voltage is supplied to the power amplifier 11, and is adjusted to a second attenuation (e.g., Att2) larger than the first attenuation when the second power supply voltage is supplied to the power amplifier 11.

Accordingly, when a higher second power supply voltage is supplied to the power amplifier 12, a higher second bias voltage is also supplied, and therefore a change in the voltage of the operating point relative to the power supply voltage due to a change in the power supply voltage can be suppressed. Therefore, a change in the operation mode caused by a change in the power supply voltage can be suppressed, and a change in the gain characteristics in the saturation region of the power amplifier can be suppressed. As a result, the difficulty of DPD can be reduced, thereby contributing to reducing power consumption for DPD and/or reducing nonlinear distortion due to DPD. Furthermore, when a higher second power supply voltage is supplied to the power amplifier 11, the variable attenuation circuit 24 is adjusted to a larger attenuation, and a change in the gain in the linear region of the power amplifier 12 can be compensated for by a change in the attenuation of the output signal of the power amplifier 11. Therefore, a change in the gain with respect to a change in the power supply voltage in the linear region of the power amplifier circuit 1C can be suppressed, and a discontinuous change in the gain of the power amplifier circuit 1C with respect to the discrete change in the power supply voltage can be suppressed. As a result, the difficulty of DPD can be reduced, thereby contributing to reducing power consumption for DPD and/or reducing nonlinear distortion due to DPD.

### Additional Exemplary Embodiments

A power amplifier circuit and a power amplification method according to exemplary aspects of the present disclosure have been described above based on embodiments, but a power amplifier circuit and a power amplification method according to the present disclosure are not limited to the above embodiments. Other embodiments realized by combining any of the components in the above-described embodiments, modifications obtained by modifying the above-described embodiments in various ways as conceived of by one skilled in the art without departing from the spirit of the exemplary aspects, and various devices incorporating the above-described power amplifier circuit are also included in the present disclosure.

For example, in the circuit configurations of the various circuits according to the above-described embodiments, other circuit elements, wiring lines, and the like may be inserted midway along paths connecting the circuit elements and signal paths disclosed in the drawings. For example, a capacitor may be inserted between the path between the inductor 21 and the power amplifier 11 and the ground. Similarly, a capacitor may be inserted between the path between the inductor 21 and the power amplifier 12 and the ground.

Furthermore, for example, Modification 1 and Modification 2 of Embodiment 1 may be combined with each other. For example, the power amplifier circuit 1B may include the bias circuit 14A instead of the bias circuit 14.

In addition, for example, Modification 1 of Embodiment 1 may be applied to Embodiment 2. That is, the variable attenuation circuit may switch the attenuation depending on the tracking mode. Specifically, the variable attenuation circuit may be adjusted to a greater attenuation as the power supply voltage increases in the D-ET mode or SPT mode and be adjusted to a smaller attenuation as the power supply voltage decreases in the APT mode.

It is noted that in the above-described embodiments, the number of discrete voltages that can be supplied from the tracker circuit to the power amplifier circuit is four but is not limited to this number. The number of discrete voltages may be more than four or less than four as would be appreciated to one skilled in the art.

The present disclosure can be widely used in communication devices such as mobile phones as a power amplifier circuit for amplifying radio frequency signals.

### REFERENCE SIGNS LIST

1, 1A, 1B, 1C power amplifier circuit
2 tracker circuit
3 RFIC
4 BBIC
5 antenna
6, 6A, 6B, 6C communication device
7 module substrate
8, 8C, 9 integrated circuit
11, 12, 13 power amplifier
14, 14A, 14C, 15, 16 bias circuit
17, 18, 19 matching circuit
20 PA control circuit
21 inductor
22, 23 phase shift circuit
24 variable attenuation circuit
30 antenna connection terminal
31 radio-frequency input terminal
32 power supply voltage terminal
33 control terminal

1. A power amplifier circuit comprising:
a first power amplifier configured to amplify a radio frequency signal using multiple discrete voltages including a first power supply voltage and a second power supply voltage that is higher than the first power supply voltage;
a second power amplifier configured to amplify the radio frequency signal amplified by the first power amplifier using the multiple discrete voltages;
a first bias circuit configured to supply:
a first bias voltage to the first power amplifier when the first power supply voltage is supplied to the first power amplifier, and
a second bias voltage lower than the first bias voltage to the first power amplifier when the second power supply voltage is supplied to the first power amplifier; and
a second bias circuit configured to supply:
a third bias voltage to the second power amplifier when the first power supply voltage is supplied to the second power amplifier, and
a fourth bias voltage higher than the third bias voltage to the second power amplifier when the second power supply voltage is supplied to the second power amplifier.

2. The power amplifier circuit according to claim 1, wherein:
the first bias circuit is configured to supply a lower bias voltage to the first power amplifier as the power supply voltage supplied to the first power amplifier increases, and
the second bias circuit is configured to supply a higher bias voltage to the second power amplifier as the power supply voltage supplied to the second power amplifier increases.

3. The power amplifier circuit according to claim 1, wherein the first bias circuit is configured to switch the bias voltage supplied to the first power amplifier based on a tracking mode applied to the first power amplifier.

4. The power amplifier circuit according to claim 3, wherein, when a D-ET mode or an SPT mode is applied to the first power amplifier, the first bias circuit is configured to supply:
the first bias voltage to the first power amplifier when the first power supply voltage is supplied to the first power amplifier, and
the second bias voltage, which is lower than the first bias voltage, to the first power amplifier when the second power supply voltage is supplied to the first power amplifier.

5. The power amplifier circuit according to claim 4, wherein, when an APT mode is applied to the first power amplifier, the first bias circuit is configured to supply:
a fifth bias voltage to the first power amplifier when the first power supply voltage is supplied to the first power amplifier, and
a sixth bias voltage, which is higher than the fifth bias voltage, to the first power amplifier when the second power supply voltage is supplied to the first power amplifier.

6. The power amplifier circuit according to claim 5, wherein the first bias circuit is configured to supply:
a lower bias voltage to the first power amplifier as the power supply voltage supplied to the first power amplifier increases when the D-ET mode or SPT mode is applied to the first power amplifier, and
a higher bias voltage to the first power amplifier as the power supply voltage supplied to the first power amplifier increases when the APT mode is applied to the first power amplifier.

7. The power amplifier circuit according to claim 1, further comprising an integrated circuit that includes the first power amplifier, the second power amplifier, the first bias circuit, and the second bias circuit.

8. The power amplifier circuit according to claim 7, wherein:
the first bias circuit is disposed closer to the first power amplifier than the second bias circuit, and
the second bias circuit is disposed closer to the second power amplifier than the first bias circuit.

9. The power amplifier circuit according to claim 7, wherein:
the first power amplifier is disposed closer to the first bias circuit than the second power amplifier, and
the second power amplifier is disposed closer to the second bias circuit than the first power amplifier.

10. The power amplifier circuit according to claim 1, wherein the power amplifier circuit is a Doherty amplifier circuit, and further includes a third power amplifier as a peak amplifier, and the second power amplifier is a carrier amplifier.

11. The power amplifier circuit according to claim 10, further comprising a third bias circuit configured to supply:
a seventh bias voltage to the third power amplifier when the first power supply voltage is supplied to the third power amplifier, and
an eighth bias voltage lower than the seventh bias voltage to the third power amplifier when the second power supply voltage is supplied to the third power amplifier.

12. The power amplifier circuit according to claim 11, wherein the third bias circuit is configured to supply a lower bias voltage to the third power amplifier as the power supply voltage supplied to the third power amplifier increases.

13. A power amplifier circuit comprising:
a first power amplifier configured to amplify a radio frequency signal using multiple discrete voltages that includes a first power supply voltage and a second power supply voltage that is higher than the first power supply voltage;
a second power amplifier configured to amplify the radio frequency signal amplified by the first power amplifier using the multiple discrete voltages;
a first bias circuit configured to supply a bias voltage to the first power amplifier;
a second bias circuit configured to supply:
a first bias voltage to the second power amplifier when the first power supply voltage is supplied to the second power amplifier, and
a second bias voltage, which is higher than the first bias voltage, to the second power amplifier when the second power supply voltage is supplied to the second power amplifier; and
a variable attenuation circuit connected to an input terminal of the first power amplifier or connected between an output terminal of the first power amplifier and an input terminal of the second power amplifier,
wherein the variable attenuation circuit is configured to adjust to a first attenuation when the first power supply voltage is supplied to the first power amplifier, and to a second attenuation, which is greater than the first attenuation, when the second power supply voltage is supplied to the first power amplifier.

14. A power amplification method for amplifying a radio frequency signal using multiple discrete voltages, the method comprising:
receiving a first power supply voltage included in the multiple discrete voltages;
supplying a first bias voltage to a first power amplifier based on the first power supply voltage;
amplifying a first radio frequency signal in the first power amplifier using the first power supply voltage and the first bias voltage;
supplying a third bias voltage to a second power amplifier based on the first power supply voltage;
amplifying the first radio frequency signal amplified in the first power amplifier in the second power amplifier using the first power supply voltage and the third bias voltage;
receiving a second power supply voltage that is included in the multiple discrete voltages and is higher than the first power supply voltage;
supplying a second bias voltage, which is lower than the first bias voltage, to the first power amplifier based on the second power supply voltage;
amplifying a second radio frequency signal in the first power amplifier using the second power supply voltage and the second bias voltage;
supplying a fourth bias voltage, which is higher than the third bias voltage, to the second power amplifier based on the second power supply voltage; and
amplifying the second radio frequency signal amplified in the first power amplifier in the second power amplifier using the second power supply voltage and the fourth bias voltage.

15. The power amplification method according to claim 14, further comprising:
supplying a lower bias voltage to the first power amplifier as the power supply voltage supplied to the first power amplifier increases; and
supplying a higher bias voltage to the second power amplifier as the power supply voltage supplied to the second power amplifier increases.

16. The power amplification method according to claim 14, further comprising switching the bias voltage supplied to the first power amplifier based on a tracking mode applied to the first power amplifier.

17. The power amplification method according to claim 16, further comprising supplying, when a D-ET mode or an SPT mode is applied to the first power amplifier:
the first bias voltage to the first power amplifier when the first power supply voltage is supplied to the first power amplifier, and
the second bias voltage, which is lower than the first bias voltage, to the first power amplifier when the second power supply voltage is supplied to the first power amplifier.

18. The power amplification method according to claim 17, further comprising supplying, when an APT mode is applied to the first power amplifier:
a fifth bias voltage to the first power amplifier when the first power supply voltage is supplied to the first power amplifier, and
a sixth bias voltage, which is higher than the fifth bias voltage, to the first power amplifier when the second power supply voltage is supplied to the first power amplifier.

19. The power amplification method according to claim 18, further comprising supplying:
a lower bias voltage to the first power amplifier as the power supply voltage supplied to the first power amplifier increases when the D-ET mode or SPT mode is applied to the first power amplifier, and
a higher bias voltage to the first power amplifier as the power supply voltage supplied to the first power amplifier increases when the APT mode is applied to the first power amplifier.
